(19) United States
(12) Patent Application Publication
(10) Pub. No.: US 2025/0329642 A1
(43) Pub. Date: Oct. 23, 2025

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Yonggang Yang, Wuhan (CN); Xiaofen Zheng, Wuhan (CN); Yuhuan Zheng, Wuhan (CN)

(21) Appl. No.: 18/676,255

(22) Filed: May 28, 2024

Related U.S. Application Data
(63) Continuation of application No. PCT/CN2024/088768, filed on Apr. 19, 2024.

(51) Int. Cl. H01L 23/528; H10B 41/10; H10B 41/27; H10B 41/35; H10B 43/10; H10B 43/27; H10B 43/35

(52) U.S. Cl. CPC H01L 23/5283; H01L 23/528; H10B 41/10; H10B 41/27; H10B 41/35; H10B 43/10; H10B 43/27; H10B 43/35

(57) ABSTRACT

In certain aspects, a three-dimensional (3D) memory device includes channel structures in a first region, and a contact structure in a dielectric portion of a second region and including a vertical interconnect and an interconnect line in contact with the vertical interconnect. The first and second regions are arranged in a first direction. The 3D memory device also includes a conductive layer extending in the first region and a conductive portion of the second region. The dielectric and conductive portions of the second region are arranged in a second direction perpendicular to the first direction. The interconnect line of the contact structure extends in the second direction and is in contact with the conductive layer. The 3D memory device further includes high dielectric constant (high-k) dielectric layers, and liner plugs between the interconnect line of the conductive layer and the high-k dielectric layers in the second direction. At least a part of the conductive layer is sandwiched between the high-k dielectric layers.

### CROSS-REFERENCE TO RELATED APPLICATIONS

This application is a continuation of International Application No. PCT/CN2024/088768, filed on Apr. 19, 2024, which is hereby incorporated by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, a 3D memory device includes channel structures in a first region, and a first contact structure in a dielectric portion of a second region and including a vertical interconnect and an interconnect line in contact with the vertical interconnect. The first region and the second region are arranged in a first direction. The 3D memory device also includes a first conductive layer extending in the first region and a conductive portion of the second region. The dielectric portion and the conductive portion of the second region are arranged in a second direction perpendicular to the first direction. The interconnect line of the first contact structure extends in the second direction and is in contact with the first conductive layer. The 3D memory device further includes first high dielectric constant (high-k) dielectric layers, and liner plugs between the interconnect line of the first contact structure and the first high-k dielectric layers in the second direction. A part of the first conductive layer is sandwiched between the first high-k dielectric layers.

In some implementations, the liner plugs include at least one of silicon nitride, silicon oxynitride, or silicon carbon nitride, and the first high-k dielectric layers include aluminum oxide.

In some implementations, another part of the first conductive layer is sandwiched between the liner plugs.

In some implementations, each of the liner plugs includes a plurality of portions.

In some implementations, the 3D memory device further includes a second contact structure in the dielectric portion of the second region and including a vertical interconnect and an interconnect line in contact with the vertical interconnect, a second conductive layer extending in the first region and the conductive portion of the second region, and second high-k dielectric layers, at least a part of the second conductive layer being sandwiched between the second high-k dielectric layers. In some implementations, the interconnect line of the second contact structure extends in the second direction and is in contact with the second conductive layer and the second high-k dielectric layers.

In some implementations, the dielectric portion of the second region includes a stack structure including interleaved first dielectric layers and second dielectric layers. In some implementations, the first contact structure and the second contact structure extend into the stack structure at different depths.

In some implementations, each of the interconnect lines in the first and second contact structures is sandwiched between two of the first dielectric layers in the stack structure.

In some implementations, the 3D memory device further includes additional conductive layers each extending in the first region and the conductive portion of the second region, and additional high-k dielectric layers, each of the additional conductive layers being sandwiched between a respective one of the additional high-k dielectric layers. In some implementations, each of the second dielectric layers in the stack structure is in contact with a respective one of the additional high-k dielectric layers.

In some implementations, the first dielectric layers include silicon oxide, and the second dielectric layers include silicon nitride.

In another aspect, a system includes a 3D memory device configured to store data. The 3D memory device includes channel structures in a first region, and a first contact structure in a dielectric portion of a second region and including a vertical interconnect and an interconnect line in contact with the vertical interconnect. The first region and the second region are arranged in a first direction. The 3D memory device also includes a first conductive layer extending in the first region and a conductive portion of the second region. The dielectric portion and the conductive portion of the second region are arranged in a second direction perpendicular to the first direction. The interconnect line of the first contact structure extends in the second direction and is in contact with the first conductive layer. The 3D memory device further includes first high-k dielectric layers, and liner plugs between the interconnect line of the first contact structure and the first high-k dielectric layers in the second direction. A part of the first conductive layer is sandwiched between the first high-k dielectric layers. The system also includes a memory controller electrically connected to the 3D memory device and configured to operate the channel structures through the conductive layer.

In still another aspect, a method for forming a 3D memory device is disclosed. A stack structure including interleaved first dielectric layers and second dielectric layers is formed. Parts of the second dielectric layers are replaced with conductive layers surrounded by high-k dielectric layers. An opening extending into a part of the stack structure including the interleaved first dielectric layers and remainders of the second dielectric layers is formed to expose the remainder of a respective one of second dielectric layers. At least a part of the exposed second dielectric layer and a part of the high-k dielectric layer surrounding a respective one of the conductive layers are removed through the opening to expose the conductive layer. A liner layer is formed through the opening on the exposed conductive layer and a remainder of the high-k dielectric layer. A part of the liner layer is removed through the opening to expose the conductive layer again. An interconnect line in contact with the exposed conductive layer is formed through the opening.

In some implementations, to form the liner layer, at least one of silicon nitride, silicon oxynitride, or silicon carbon nitride is deposited using atomic layer deposition (ALD).

In some implementations, the remainder of the high-k dielectric layer is intact when removing the part of the liner layer.

In some implementations, another opening extending into the part of the stack structure is formed to expose the remainder of a respective another one of second dielectric layers, and at least a part of the exposed another second dielectric layer is removed through the another opening. In some implementations, a respective another one of the conductive layers and another high-k dielectric layer surrounding the another conductive layer are intact when removing the at least part of the exposed another second dielectric layer.

In some implementations, the at least part of the exposed another second dielectric layer is removed in a same process as the at least part of the exposed second dielectric layer and the part of the high-k dielectric layer.

In some implementations, another liner layer is formed through the another opening on a remainder of the another second dielectric layer, the remainder of the another second dielectric layer, the another liner layer, and part of the another high-k dielectric layer are removed through the another opening to expose the another conductive layer, and another interconnect line in contact with the exposed another conductive layer is formed through the another opening.

In some implementations, the another liner layer is formed in a same process as the another liner layer. In some implementations, the another second dielectric layer, the another liner layer, and the part of the another high-k dielectric layer are removed in a same process as the part of the liner layer.

In some implementations, after removing the part of the liner layer to expose the conductive layer again, an additional liner layer is formed through the opening on the exposed conductive layer and a remainder of the liner layer, and a part of the additional liner layer is removed through the opening to expose the conductive layer again.

In some implementations, channel structures extending through the first dielectric layers and the second dielectric layers are formed in a first region of the stack structure, and before forming the opening, all the second dielectric layers in the first region and the parts of the second dielectric layers in a second region of the stack structure are replaced with the conductive layers surrounded by the high-k dielectric layers.

In some implementations, the second dielectric layers include silicon nitride, and the high-k dielectric layers include aluminum oxide.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a plan view of a 3D memory device having contact structures, according to some aspects of the present disclosure.

FIG. 2 illustrates a top perspective view of a 3D memory device having contact structures, according to some aspects of the present disclosure.

FIG. 3 illustrates an enlarged top perspective view of a 3D memory device having contact structures, according to some aspects of the present disclosure.

FIG. 4 illustrates a cross-sectional side view of a 3D memory device having contact structures, according to some aspects of the present disclosure.

FIG. 5 illustrates cross-sectional side views of a 3D memory device having a contact structure, according to some aspects of the present disclosure.

FIG. 6 illustrates enlarged cross-sectional side views of the 3D memory device in FIG. 5, according to some aspects of the present disclosure.

FIG. 7 illustrates enlarged cross-sectional side views of a 3D memory device having a contact structure with liner plugs and another contact structure without liner plugs, according to some aspects of the present disclosure.

FIGS. 8A-8C illustrate enlarged cross-sectional side views of various examples of a conductive layer, a high-k dielectric layer, an interconnect line, and liner plugs of the 3D memory device in FIG. 7, according to some aspects of the present disclosure.

FIGS. 9A-9I illustrate a fabrication process for forming a 3D memory device before forming contact structures, according to some aspects of the present disclosure.

FIGS. 10A-10E illustrate a fabrication process for forming contact structures of a 3D memory device, according to some aspects of the present disclosure.

FIG. 11 is a flowchart of a method for forming a 3D memory device having contact structures, according to some aspects of the present disclosure.

FIG. 12 illustrates a block diagram of an exemplary system having a 3D memory device, according to some aspects of the present disclosure.

FIG. 13A illustrates a diagram of an exemplary memory card having a 3D memory device, according to some aspects of the present disclosure.

FIG. 13B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnects are formed) and one or more dielectric layers.

In some 3D memory devices, such as 3D NAND memory devices, memory cells for storing data are vertically stacked through a stack structure (e.g., a memory stack) in vertical channel structures. 3D memory devices usually include staircase structures formed on one or more sides (edges), or at the center, of the stacked storage structure for purposes, such as word line pick-up/fan-out, using word line contacts landed onto different steps/levels of a staircase structure. Dummy channel structures are usually formed through the memory stack in regions outside of the core array region in which the channel structures of 3D NAND memory devices are formed, such as staircase regions having the staircase structures, to provide mechanical support to the stack structure, in particular, during the gate replacement process that temporarily removes some layers of the stack structure through slit openings across the core array region and staircase regions of the stack structure.

The integration of the various structures, such as dummy channel structures, word line contacts, staircase structures, slit openings, etc., from both the device design perspective and the fabrication process perspective, has become more and more challenging as the memory cell density of the 3D NAND memory devices continues increasing.

Contact structures (e.g., word line pick-up structures) are introduced to achieve the word line pick-up/fan-out functions without using staircase structures and word line contacts. For example, the two structures—staircase structure and word line contact, as well as their separate processes, can be merged into a single contact structure in one process, thereby reducing the manufacturing cost and simplifying the process. Moreover, by replacing staircase structures and word line contacts with contact structures, the scope of the gate replacement process can be reduced, such that at least some of the dummy channel structures can be eliminated as well to further reduce the cost and simplify the process.

The contact structures can be formed either before the gate replacement process (a.k.a. “contact first” process) or after the gate replacement process (a.k.a. “contact last” process). In the contact last process, when replacing the dielectric layers (e.g., silicon nitride layers) with the interconnect lines of contact structures using wet etching, the high dielectric constant (high-k) dielectric layers (e.g., aluminum oxide layers) surrounding the corresponding word lines may be over etched as well by the etchant (e.g., phosphoric acid). The loss of the high-k dielectric layers in this step may cause the bending of the surrounding word lines, thereby causing mechanical and/or electrical failure of the memory device. To compensate for the loss of the high-k dielectric layers, an additional deposition process (e.g., atomic layer deposition (ALD)) of the high-k material may be used, which, however, can significantly increase the process cost. Or a new etchant, including fluorine (F), with a higher etching selectivity over the high-k materials compared with the current etchant (e.g., phosphoric acid) may be developed to etch the dielectric layers. However, the new etchant may increase the process cost and complexity as well as damage nearby silicon oxide layers with its fluorine.

To address one or more of the aforementioned issues, the present disclosure introduces a liner layer (e.g., silicon oxynitride, silicon nitride, or silicon carbon nitride layer) as a sacrificial layer to protect the high-k dielectric layer (e.g., aluminum oxide layer) when replacing the dielectric layer (e.g., silicon nitride layers) with the interconnect line of the contact structure using traditional etchant (e.g., phosphoric acid) in the contact last process. The liner layer can protect the high-k dielectric layer from the etchant, thereby controlling the amount of high-k material loss without having an additional deposition process (e.g., ALD) of the high-k material or using a new etchant that may cause fluorine attack to the silicon oxide layer. Thus, the process window of etching dielectric layers can be enlarged, the reliance on new etchants with a higher etching selectivity can be reduced, and the limitations on the etching process can be eased.

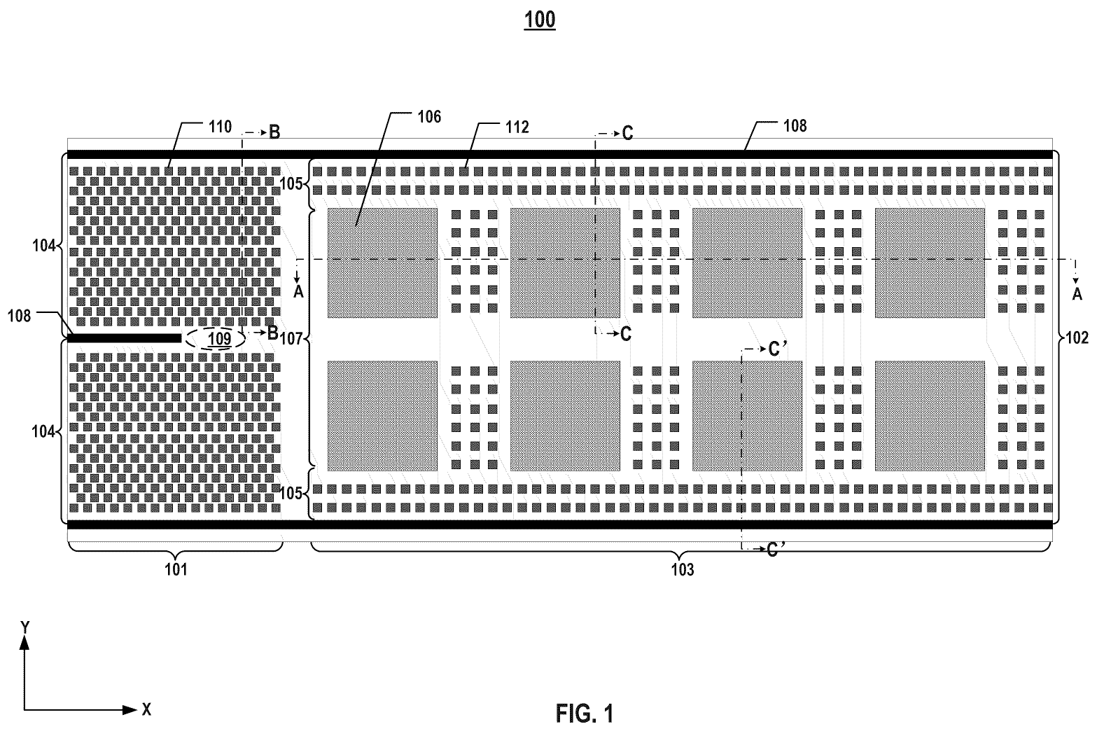

FIG. 1 illustrates a plan view of a 3D memory device 100 having contact structures 106, according to some aspects of the present disclosure. In some implementations, 3D memory device 100 is a NAND Flash memory device in which memory cells are provided in the form of an array of NAND memory strings. It is noted that the x and y axes are included in FIG. 1 to illustrate two orthogonal (perpendicular) directions in the wafer plane. The x-direction is the word line direction of 3D memory device 100, and the y-direction is the bit line direction of 3D memory device 100.

As shown in FIG. 1, 3D memory device 100 can include one or more blocks 102 arranged in the y-direction (the bit line direction) separated by parallel slit structures 108, such as gate line slits (GLSs). In some implementations in which 3D memory device 100 is a NAND Flash memory device, each block 102 is the smallest erasable unit of the NAND Flash memory device. Each block 102 can further include multiple fingers 104 in the y-direction separated by some of slit structures 108 with “H” cuts 109.

As shown in FIG. 1, 3D memory device 100 can be divided into at least a core array region 101 (e.g., a first region) in which an array of channel structures 110 are formed, as well as a word line pick-up region 103 (e.g., a second region) in which contact structures 106 (e.g., word line pick-up structures) are formed. Core array region 101 and word line pick-up region 103 are arranged in the x-direction (the word line direction), according to some implementations. It is understood that although one core array region 101 and one word line pick-up region 103 are illustrated in FIG. 1, multiple core array regions 101 and/or multiple word line pick-up regions 103 may be included in 3D memory device 100, for example, one word line pick-up region 103 between two core array regions 101 in the x-direction, in other examples. It is also understood that FIG. 1 only illustrates portions of core array region 101 that are adjacent to word line pick-up region 103.

As described below in detail, word line pick-up region 103 can include conductive portions 105 and dielectric portions 107 arranged in the y-direction. As shown in FIG. 1, contact structures 106 are disposed in dielectric portion 107, while dummy channel structures 112 are disposed in conductive portion 105 of word line pick-up region 103 to provide mechanical support and/or load balancing, according to some implementations. In some implementations (e.g., as shown in FIG. 1), dummy channel structures 112 are disposed in dielectric portion 107 of word line pick-up region 103 as well, for example, between contact structures 106 in the x-direction. In some implementations, dummy channel structures 112 are not disposed in dielectric portion 107 of word line pick-up region 103, i.e., only in conductive portion 105 of word line pick-up region 103. As shown in FIG. 1, each finger 104 of 3D memory device 100 can include one row of contact structures 106 disposed in dielectric portion 107 of word line pick-up region 103. It is understood that the layout and arrangement of contact structures 106, as well as the shape of each contact structure 106, may vary in different examples.

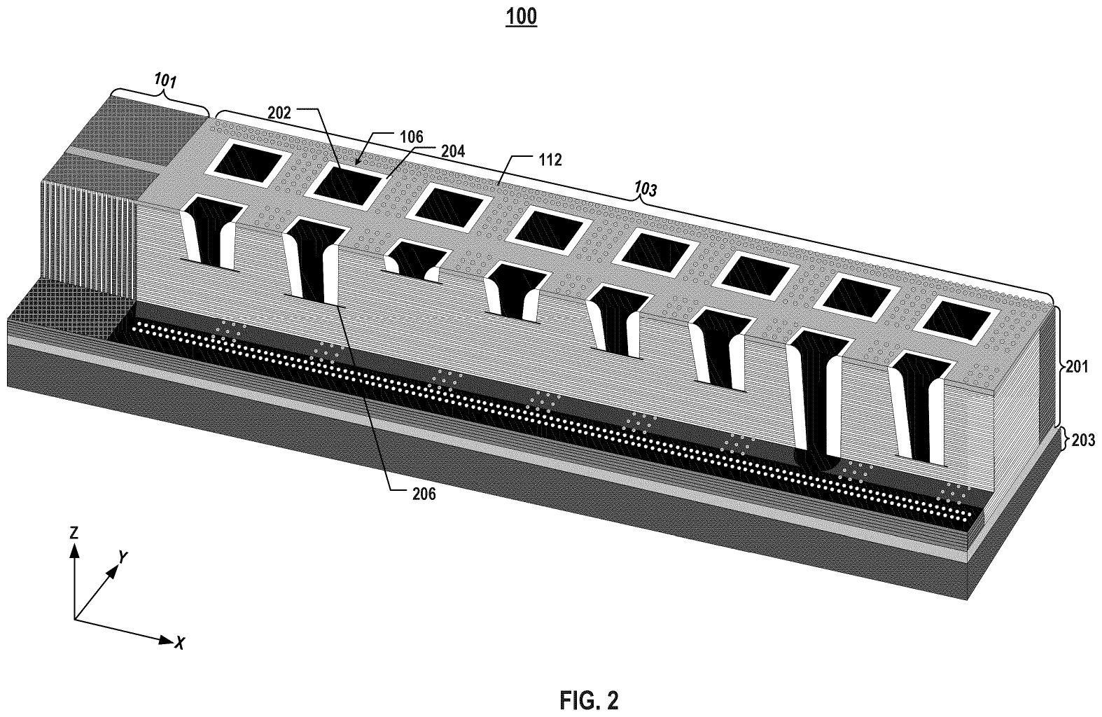

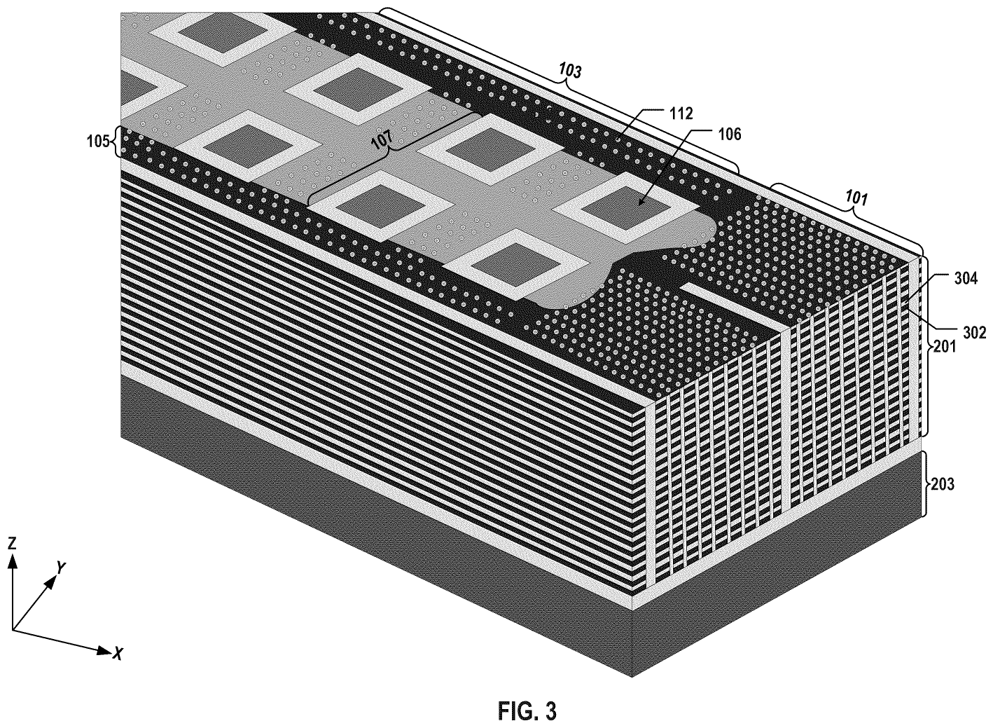

FIG. 2 illustrates a top perspective view of 3D memory device 100 having contact structures 106, according to some aspects of the present disclosure. FIG. 3 illustrates an enlarged top perspective view of 3D memory device 100 having contact structures 106, according to some aspects of the present disclosure. As shown in FIGS. 2 and 3, a stack structure 201 can be formed on a substrate 203, which can include silicon (e.g., single crystalline silicon), silicon germanium (SiGe), gallium arsenide (GaAs), germanium (Ge), silicon on insulator (SOI), or any other suitable materials. In some implementations, substrate 203 includes single crystalline silicon, which is part of the wafer on which 3D memory device 100 is fabricated, either in its native thickness or being thinned. In some implementations, substrate 203 includes, for example, polysilicon, which is a semiconductor layer replacing the part of wafer on which 3D memory device 100 is fabricated. It is noted that the x, y, and z axes are included in FIGS. 2 and 3 to further illustrate the spatial relationship of the components in 3D memory device 100. Substrate 203 of 3D memory device 100 includes two lateral surfaces extending laterally in the x-y plane: a top surface on the front side of the wafer on which stack structure 201 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of 3D memory device 100 is determined relative to substrate 203 of 3D memory device 100 in the z-direction (the vertical direction perpendicular to the x-y plane) when substrate 203 is positioned in the lowest plane of 3D memory device 100 in the z-direction. The same notion for describing the spatial relationship is applied throughout the present disclosure.

As shown in FIG. 3, stack structure 201 can include vertically interleaved first material layers 302 and second material layers 304 that are different from first material layers 302. First material layers 302 and second material layers 304 can alternate in the vertical direction (the z-direction). In some implementations, stack structure 201 can include a plurality of material layer pairs stacked vertically in the z-direction, each of which includes first material layer 302 and second material layer 304. The number of material layer pairs in stack structure 201 can determine the number of memory cells in 3D memory device 100.

In some implementations, 3D memory device 100 is a NAND Flash memory device, and stack structure 201 is a stacked storage structure through which NAND memory strings are formed. As shown in FIG. 3, second material layers 304 can have different materials in different regions/portions of 3D memory device 100. Thus, stack structure 201 may be viewed as having a number of stack structures with different materials of second material layers 304 for ease of description in the present disclosure. In some implementations, core array region 101 and conductive portion 105 of word line pick-up region 103 include a conductive stack structure having interleaved conductive layers and first dielectric layers. That is, second material layers 304 of stack structure 201 may be conductive layers in core array region 101 and conductive portion 105 of word line pick-up region 103. In some implementations, dielectric portion 107 of word line pick-up region 103 includes a dielectric stack structure having interleaved second dielectric layers and the first dielectric layers. That is, second material layers 304 of stack structure 201 may be the second dielectric layers in dielectric portion 107 of word line pick-up region 103. First material layers 302 of stack structure may be the same—the first dielectric layers—in the conductive stack structure and the dielectric stack structure across core array region 101 and word line pick-up region 103. As described below in detail with respect to the fabrication process, the formation of stack structure 201 with different materials of second material layer 304 in different regions/portions can be achieved by controlling the different degrees and scopes of the gate replacement process in different regions/portions. For example, stack structure 201 may have undergone a complete gate replacement process in core array region 101 to replace all the second dielectric layers with the conductive layers, but a partial gate replacement process in word line pick-up region 103 to replace some of the second dielectric layers with the conductive layers in conductive portion 105, leaving the remainders of the second dielectric layers in dielectric portion 107.

In some implementations, each conductive layer in the conductive stack structure in core array region 101 and conductive portion 105 of word line pick-up region 103 functions as a gate line of the NAND memory strings (in the forms of channel structures 110) in core array region 101, as well as a word line extending laterally from the gate line and ending in conductive portion 105 of word line pick-up region 103 for word line pick-up/fan-out through contact structures 106. The word lines (i.e., the conductive layers) at different depths/level of the conductive stack structure each extends laterally in core array region 101 and conductive portion 105 of word line pick-up region 103, but are discontinuous (e.g., being replaced by the second dielectric layers) in dielectric portion 107 of word line pick-up region 103, according to some implementations.

The conductive layers can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. The dielectric layers can include dielectric materials including, but not limited to, silicon oxide, silicon nitride, silicon oxynitride, or any combination thereof. The first dielectric layers and the second dielectric layers can have different dielectric materials, such as silicon oxide and silicon nitride. In some implementations, the conductive layers include metals, such as tungsten, the first dielectric layers include silicon oxide, and the second dielectric layers include silicon nitride. For example, first material layers 302 of stack structure 201 may include silicon oxide across core array region 101 and word line pick-up region 103, and second material layers 304 of stack structure 201 may include tungsten in core array region 101 and conductive portion 105 of word line pick-up region 103 and silicon nitride in dielectric portion 107 of word line pick-up region 103.

As shown in FIGS. 2 and 3, the heights of stack structure 201 (e.g., the conductive stack structure and the dielectric stack structure) are uniform in core array region 101 and in word line pick-up region 103, according to some implementations. Different from some 3D memory devices that include one or more staircase structures in a staircase region (corresponding to word line pick-up region 103 for word line pick-up/fan-out), which has non-uniform heights of the stack structure in the staircase region, 3D memory device 100 can eliminate the staircase structures while still achieving the word line pick-up/fan-out function using contact structures 106, as described below in detail.

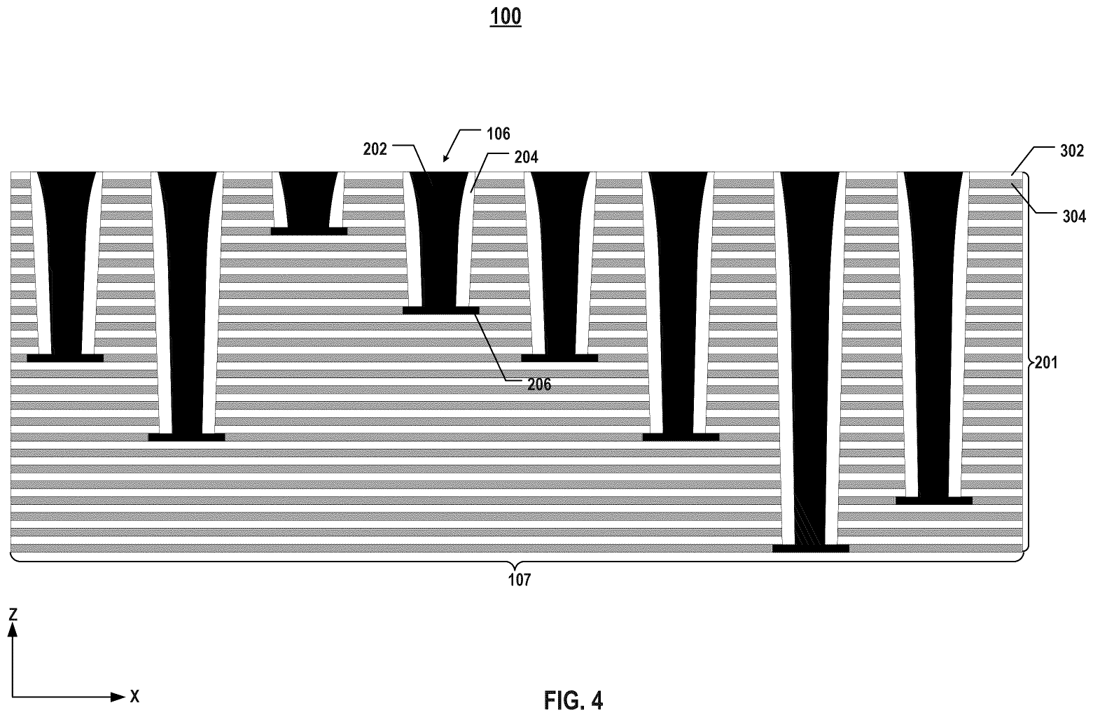

FIG. 4 illustrates a cross-sectional side view of 3D memory device 100 having contact structures 106, according to some aspects of the present disclosure. The cross-section may be along the AA direction in dielectric portion 107 of word line pick-up region 103 in FIG. 1. As shown in FIG. 4, contact structures 106 extend vertically into stack structure 201 (the dielectric stack structure in dielectric portion 107 of word line pick-up region 103) at different depths in the z-direction, according to some implementations. The top surfaces of different contact structures 106 can be flush with one another, while the bottom surfaces of different contact structures 106 can extend to different levels, for example, different second material layers 304 of stack structure 201.

In some implementations, contact structure 106 includes a vertical interconnect 202, a contact spacer 204 circumscribing vertical interconnect 202, and an interconnect line 206 below and in contact with vertical interconnect 202. Vertical interconnect 202 and interconnect line 206 can include conductive materials including, but not limited to, W, Co, Cu, Al, TiN, polysilicon, doped silicon, silicides, or any combination thereof. Contact spacer 204 can include dielectric materials including, but not limited to, silicon oxide, silicon nitride, silicon oxynitride, or any combination thereof. In some implementations, vertical interconnect 202 and interconnect line 206 include TiN/W, and contact spacer 204 includes silicon oxide.

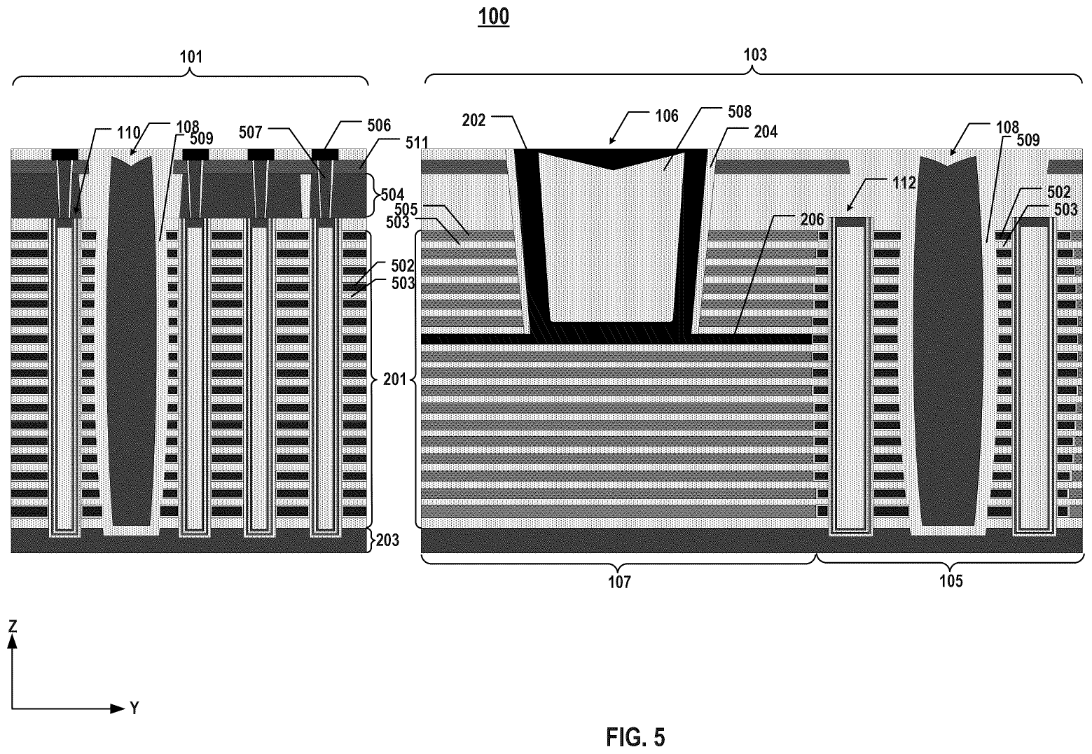

FIG. 5 illustrates cross-sectional side views of 3D memory device 100 having contact structures 106, according to some aspects of the present disclosure. One cross-section (on the left side of FIG. 5) may be along the BB direction in core array region 101 in FIG. 1, and another cross-section (on the right side of FIG. 5) may be along the CC direction in word line pick-up region 103 in FIG. 1. As shown in FIG. 5, 3D memory device 100 can include channel structures 110 in core array region 101. Each channel structure 110 can extend vertically through interleaved conductive layers 502 (word lines, e.g., tungsten) and first dielectric layers 503 (e.g., silicon oxide) of the conductive stack structure of stack structure 201 into substrate 203. 3D memory device 100 can also include dummy channel structures 112 in conductive portion 105 of word line pick-up region 103. Each dummy channel structure 112 can extend vertically through interleaved conductive layers 502 and first dielectric layers 503 of the conductive stack structure of stack structure 201 into substrate 203. 3D memory device 100 can further include slit structures 108 across core array region 101 and core array region 101. Each slit structure 108 can extend vertically through interleaved conductive layers 502 and first dielectric layers 503 of the conductive stack structure of stack structure 201 into substrate 203 as well.

As shown in FIG. 5, slit structure 108 can include a slit spacer 509 that separates conductive layers 502 between different blocks 102. In some implementations, slit structure 108 is an insulating structure that does not include any interconnects therein (i.e., not functioning as the source contact) and thus, does not introduce parasitic capacitance and leakage current with conductive layers 502. In some implementations, slit structure 108 is a front-side source contact further including a conductive portion (e.g., including W, polysilicon, and/or TiN) circumscribed by slit spacer 509. As described below in detail, during the gate replacement process, the slit in which slit structure 108 is formed can serve as the passageway and starting point for forming conductive layers 502. As a result, slit structure 108 is surrounded by conductive layers 502 in either core array region 101 or conductive portion 105 of word line pick-up region 103.

As shown in FIG. 5, in some implementations, 3D memory device 100 further includes a plurality of drain select gate (DSG) channel structures 507 above and in contact with the upper ends of channel structures 110, respectively. 3D memory device 100 can further include a DSG layer 504 including a semiconductor layer (e.g., polysilicon layer) on stack structure 201 in core array region 101, but not in word line pick-up region 103, for example, as shown in FIG. 5. Each DSG channel structure 507 can extend vertically through DSG layer 504 to be in contact with the upper end of a corresponding channel structure 110. In some implementations, 3D memory device 100 further includes a stop layer 511 (e.g., silicon nitride layer) on DSG layer 504. DSG channel structure 507 can include a semiconductor layer (e.g., polysilicon) and a spacer surrounding the semiconductor layer. In some implementations, 3D memory device 100 includes a DSG stack including one or more DSG layers and one or more dielectric layers (e.g., silicon oxide layers) interleaved stacked above stack structure 201.

As shown in FIG. 5, 3D memory device 100 can further include a local contact layer above stop layer 511 and stack structure 201. In some implementations, the local contact layer includes various local contact structures, such as channel contacts 506 (a.k.a. bit line contacts) above and in contact with DSG channel structures 507 in core array region 101. The local contact layer can further include one or more interlayer dielectric (ILD) layers (also known as “intermetal dielectric (IMD) layers”) in which the local contact structures can form. Channel contacts 506 in the local contact layer can include conductive materials including, but not limited to, W, Co, Cu, Al, silicides, or any combination thereof. The ILD layers in the local contact layer can include dielectric materials including, but not limited to, silicon oxide, silicon nitride, silicon oxynitride, low-k dielectrics, or any combination thereof.

Instead of having staircase structures and word line contacts landed on different levels/stairs of the staircase structures, 3D memory device 100 can include stack structure 201 with uniform heights and contact structures 106 in dielectric portion 107 of word line pick-up region 103 for word line pick-up/fan-out. As shown in FIG. 5, interconnect line 206 of each contact structure 106 in dielectric portion 107 can extend laterally in the y-direction (the bit line direction) to be in contact with a corresponding conductive layer 502 in conductive portion 105 at the same level of stack structure 201. Since interconnect line 206 is in contact with vertical interconnect 202 of contact structure 106, each contact structure 106 is electrically connected to corresponding conductive layer 502 across conductive portion 105 in word line pick-up region 103 and core array region 101, according to some implementations. In other words, contact structures 106 can extend vertically through stack structure 201 at different depths to be electrically connected to the word lines at different levels, respectively, to achieve word line pick-up/fan-out.

As described below in detail, during the gate replacement process, some of second dielectric layers 505 (e.g., silicon nitride) remain intact, thereby forming the dielectric stack structure of stack structure 201 in dielectric portion 107 of word line pick-up region 103, and contact structure 106 is formed by etching first and second dielectric layers 503 and 505 in dielectric portion 107 of word line pick-up region 103. As a result, contact structures 106 extend into interleaved first and second dielectric layers 503 and 505 of the dielectric stack structure and are surrounded by first and second dielectric layers 503 and 505 in dielectric portion 107 of word line pick-up region 103, according to some implementations. The bottom of each contact structure 106 can be aligned with a corresponding second dielectric layer 505, as opposed to first dielectric layer 503, and the corresponding second dielectric layer 505 can be partially replaced with interconnect line 206 to form an electrical connection between vertical interconnect 202 of contact structure 106 and the corresponding conductive layer 502. Thus, in some implementations, interconnect line 206 is sandwiched between two first dielectric layers 503, as opposed to two second dielectric layers 505, in the dielectric stack structure in dielectric portion 107 of word line pick-up region 103.

In some implementations as shown in FIG. 5, due to the relatively large critical dimension compared with the word line contacts in some 3D memory devices caused by its fabrication process as described below in detail, contact structure 106 further includes a filler 508 circumscribed by vertical interconnect 202. That is, the contact structure opening may not be fully filled with contact spacer 204 and vertical interconnect 202, and the remaining space of the contact structure opening may be filled with dielectric materials, including, but not limited to, silicon oxide, silicon nitride, silicon oxynitride, or any combination thereof, as filler 508.

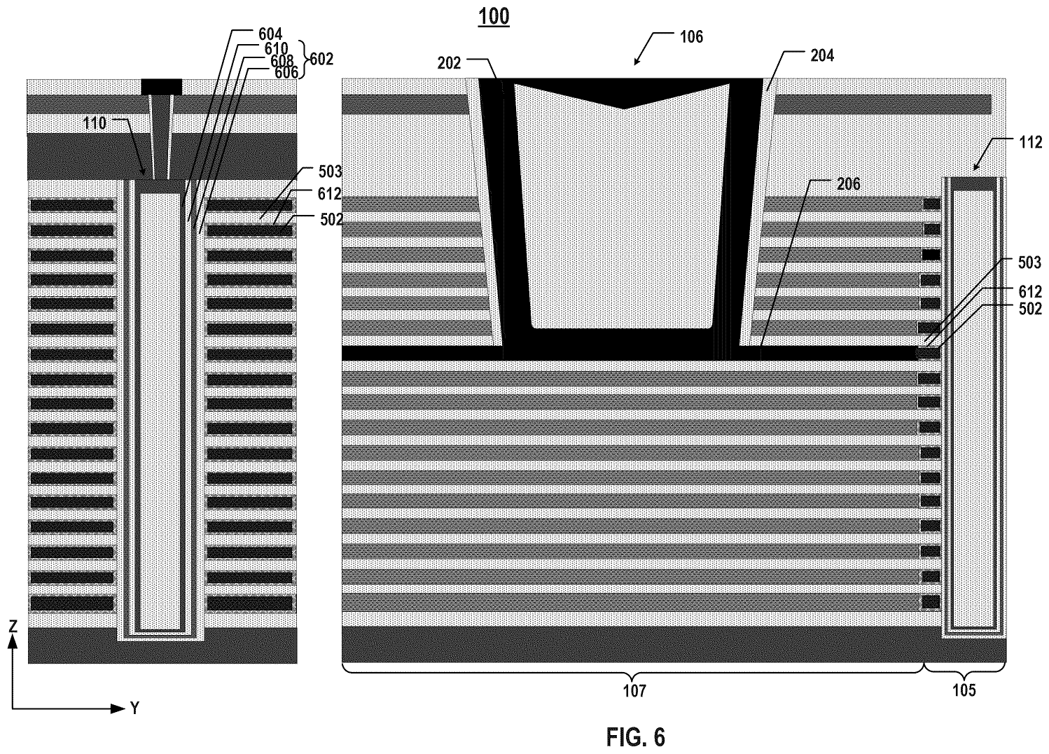

As shown in the enlarged view of FIG. 6, in some implementations, channel structure 110 includes a channel hole filled with a semiconductor layer (e.g., as a channel layer 604) and a composite dielectric layer (e.g., as a memory layer 602). In some implementations, channel layer 604 includes silicon, such as amorphous silicon, polysilicon, or single crystalline silicon. For example, channel layer 604 may include polysilicon. In some implementations, memory layer 602 is a composite layer including a tunneling layer 610, a storage layer 608 (also known as a “charge trap layer”), and a blocking layer 606. The remaining space of the channel hole can be partially or fully filled with a filler including dielectric materials, such as silicon oxide, and/or an air gap. Channel structure 110 can have a cylinder shape (e.g., a pillar shape). The filler, channel layer 604, tunneling layer 610, storage layer 608, and blocking layer 606 of memory layer 602 are arranged radially from the center toward the outer surface of the pillar in this order, according to some implementations. Tunneling layer 610 can include silicon oxide, silicon oxynitride, or any combination thereof. Storage layer 608 can include silicon nitride, silicon oxynitride, silicon, or any combination thereof. Blocking layer 606 can include silicon oxide, silicon oxynitride, or any combination thereof. In one example, memory layer 602 can include a composite layer of silicon oxide/silicon oxynitride/silicon oxide (ONO).

As shown in FIG. 6, 3D memory device 100 can further include high-k dielectric layers 612 each sandwiched between adjacent conductive layer 502 and first dielectric layer 503 in the conductive stack structure in core array region 101 and conductive portion 105 of word line pick-up region 103. As described below in detail with respect to the fabrication process, high-k dielectric layers 612 may be formed prior to the formation of conductive layers 502, such that conductive layers 502 may be formed surrounded by high-k dielectric layers 612. Parts of high-k dielectric layers 612 that are laterally between memory layer 602 of channel structure 110 and conductive layers 502 can serve as the gate dielectrics of the memory cells. High-k dielectric layers 612 can include high-k dielectric materials, such as aluminum oxide (AlO), hafnium oxide (HfO), zirconium oxide (ZrO), or any combinations thereof.

As shown in FIG. 6, compared with other high-k dielectric layers 612, part of high-k dielectric layer 612 surrounding conductive layer 502 (part of word line) that is in contact with interconnect line 206 of contact structure 106 is removed to expose conductive layer 502 such that interconnect line 206 can be electrically connected to conductive layer 502. Due to the existence of high-k dielectric layer 612 sandwiched between adjacent conductive layer 502 and first dielectric layer 503 in the conductive stack structure in core array region 101 and conductive portion 105 of word line pick-up region 103, high-k dielectric layers 612 do not need to be formed surrounding memory layer 602 of channel structures 110, according to some implementations.

In some implementations, dummy channel structure 112 has the same structure as channel structure 110, as described above with respect to FIG. 6, because they are formed in the same fabrication process. Dummy channel structure 112, however, cannot perform the same memory functions as channel structure 110, at least because dummy channel structures 112 are not in contact with any DSG channel structures 507 or any local contact structures (e.g., channel contacts 506) in the local contact layer to pick-up/fan-out dummy channel structures 112, as shown in FIG. 5, according to some implementations. It is understood that in some examples, dummy channel structures 112 and channel structure 110 may have different structures and may be formed in different fabrication processes. For example, dummy channel structures 112 may be filled with dielectric material(s) without semiconductor materials (as channel layer 604). Nevertheless, both dummy channel structures 112 and channel structures 110 can perform the mechanical supporting functions to stack structure 201, in particular, during the gate replacement process, as described below in detail with respect to the fabrication processes.

As described above, in order to form an electrical connection between vertical interconnect 202 of contact structure 106 and the corresponding conductive layer 502, the corresponding second dielectric layer 505 needs to be partially replaced with interconnect line 206, according to some implementations. As described below with respect to the fabrication process, the corresponding second dielectric layer 505 (e.g., silicon nitride layer) can be partially etched away using a wet etching process with an etchant (e.g., phosphoric acid). However, depending on the etching selectivity of the etchant over high-k dielectric layer 612, high-k dielectric layer 612 (e.g., aluminum oxide layer) may be etched as well, causing bending of the corresponding conductive layer 502 when high-k dielectric layer 612 is over etched. To mitigate the loss of high-k dielectric layer 612 when replacing part of second dielectric layer 505 with interconnect line 206, liner layers (e.g., silicon oxynitride, silicon nitride, or silicon carbon nitride) can be used as a sacrificial layer to protect high-k dielectric layer 612 from over-etching.

On the other hand, the lateral distance between the contact structure opening and conductive portion 105 of word line pick-up region 103 can vary between different contact structures 106 due to the design layout, as well as the different depths of contact structures 106, which can introduce lateral dimension variation of the contact structure openings after fabrication (e.g., overlay of different numbers of etch masks, sloped etching edge profiles, etc.). The variation of the lateral distance thus can also cause different degrees of the loss of high-k dielectric layer 612 corresponding to different contact structures 106 when etching second dielectric layers 505. For example, high-k dielectric layer 612 at a higher level of stack structure 201 may have more losses than high-k dielectric layer 612 at a lower level of stack structure 201 because high-k dielectric layer 612 at the higher level may be closer to the corresponding high-k dielectric layer 612 at a higher level than high-k dielectric layer 612 at the lower level.

Therefore, consistent with the scope of the present disclosure, to ensure all high-k dielectric layers 612 can be protected by the sacrificial liner layers from over-etching when partially replacing second dielectric layers 505 with interconnect lines 206, at least one of the liner layers, for example, the one that protects high-k dielectric layer 612 closest to the corresponding contact structure opening (e.g., the topmost one in stack structure 201), is not fully removed during the process, leaving the remainder (liner plugs) in 3D memory device 100.

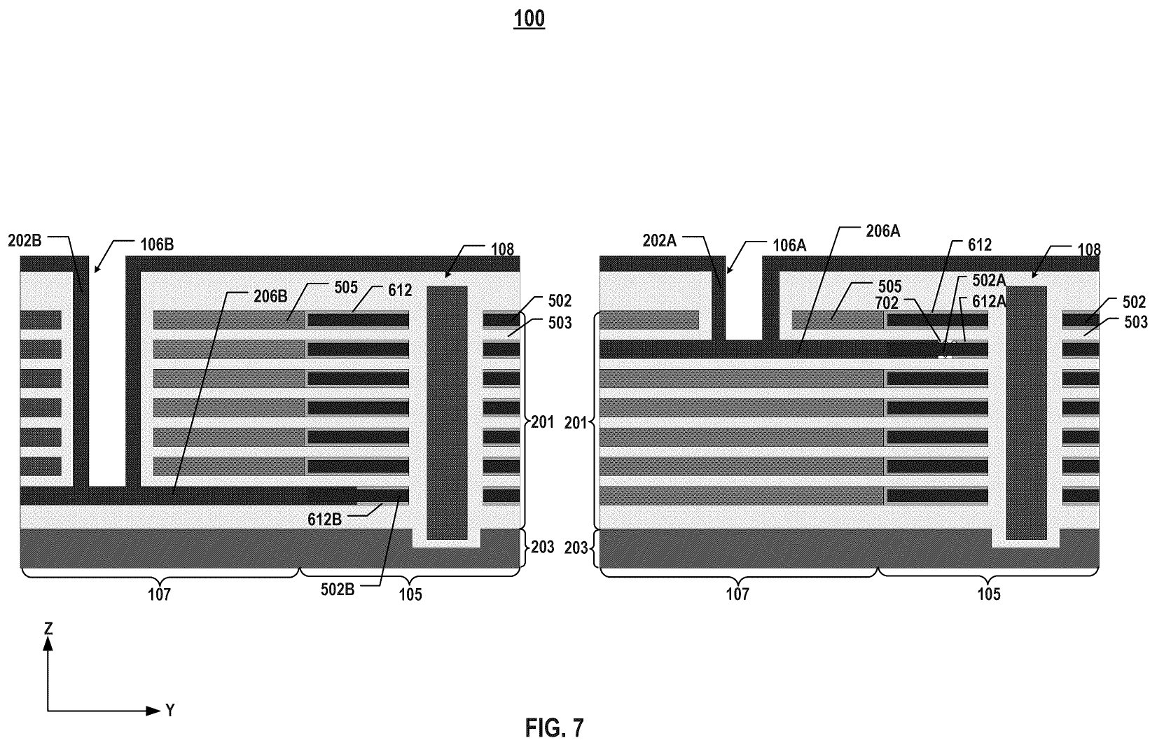

FIG. 7 illustrates enlarged cross-sectional side views of 3D memory device 100 having a first contact structure 106A with liner plugs 702 and a second contact structure 106B without liner plugs, according to some aspects of the present disclosure. One cross-section (on the left side of FIG. 7) may be along the CC direction in word line pick-up region 103 in FIG. 1, which shows second contact structure 106B without liner plugs, and another cross-section (on the right side of FIG. 7) may be along the C′C′ direction in word line pick-up region 103 in FIG. 1, which shows first contact structure 106A with liner plugs 702. As shown in FIG. 7, each of interconnect lines 206A and 206B in first and second contact structures 106A and 106B is sandwiched between two of first dielectric layers 503 in the vertical direction (the z-direction) in stack structure 201, according to some implementations. In some implementations, each of second dielectric layers 505 is in contact with a respective high-k dielectric layer 612.

As shown in FIG. 7, first contact structure 106A and second contact structure 106B extend into stack structure 201 at different depths, according to some implementations. For example, first contact structure 106A may extend further into stack structure 201 than second contact structure 106B such that interconnect line 206A of first contact structure 106A (and the bottom surface of first contact structure 106A) may be above interconnect line 206B of second contact structure 106B (and the bottom surface of second contact structure 106B) in the vertical direction (the z-direction). As described above, the lateral distance between the contact structure opening of first contact structure 106A and conductive portion 105 of word line pick-up region 103 may thus be smaller than the lateral distance between the contact structure opening of second contact structure 106B and conductive portion 105 of word line pick-up region 103, as shown in FIG. 7. As described below with respect to the fabrication process, and for the purposes of illustration without limitations, to ensure all high-k dielectric layers 612 can be protected by the sacrificial liner layers from over etching when partially replacing second dielectric layers 505 with interconnect lines 206, at least one of the liner layers, for example, the one that protects first high-k dielectric layer 612A, is not fully removed during the process, leaving liner plugs 702 (the remainder of the sacrificial liner layer) in 3D memory device 100, while at least another one of the liner layers, for example, the one that protects second high-k dielectric layer 612B, is fully removed during the process without leaving any liner plugs in 3D memory device, according to some implementations.

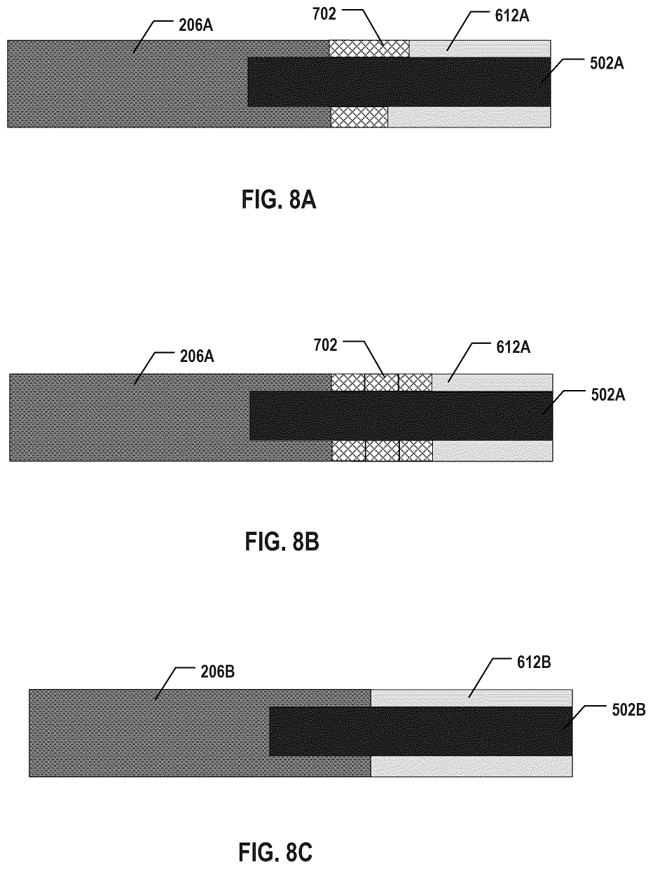

As shown in FIG. 7 and the enlarged view of FIG. 8A, interconnect line 206A of first contact structure 106A extends in the bit line direction (the y-direction) and is in contact with first conductive layer 502A, according to some implementations. A part of first conductive layer 502A can be sandwiched between first high-k dielectric layers 612A, and another part of first conductive layer 502A can be sandwiched between liner plugs 702 in the vertical direction (the z-direction). In some implementations, still another part of first conductive layer 502A is sandwiched between parts of interconnect line 206A in the vertical direction (the z-direction). In contrast, except first and second conductive layers 502A and 502B (and any other conductive layers 502 that are in contact with interconnect lines 206 of other contact structures 106 if any (not shown)), each of the rest of conductive layers 502 is sandwiched between respective high-k dielectric layers 612, but not between liner plugs 702 and/or interconnect lines 206, in the vertical direction (the z-direction), according to some implementations.

As shown in FIG. 7 and the enlarged view of FIG. 8A, in some implementations, liner plugs 702 are disposed between interconnect line 206A of first contact structure 106A and first high-k dielectric layers 612A in the bit line direction (the y-direction). Since liner plugs 702 are remainders of the liner layer used for protecting first high-k dielectric layer 612A after forming interconnect line 206A, liner plugs 702 can have the same material as the liner layer. In some implementations, liner plugs 702 includes silicon nitride, silicon oxynitride, and/or silicon carbon nitride, and first high-k dielectric layer 612A includes aluminum oxide.

As described below with respect to the fabrication process, the process of forming the sacrificial liner layers and subsequently etching second dielectric layers may be repeated multiple times to avoid excess loss of first high-k dielectric layer 612A. As a result, in some implementations, as shown in FIG. 8B, liner plugs 702 include a plurality of portions, each of which results from one of the repeated processes. It is understood that for liner plugs 702 having certain materials, such as silicon nitride, silicon oxynitride, and/or silicon carbon nitride, the interface between adjacent portions of liner plugs 702 may be distinguishable using any suitable approaches, such as testing and observing the oxygen-rich peaks. It is also understood that liner plugs 702 may include a single portion (without portion interface), as opposed to multiple portions, as shown in FIG. 8A when the process of forming the liner layer is performed only once.

As shown in FIG. 7 and the enlarged view of FIG. 8C, in some implementations, interconnect line 206B of second contact structure 106B extends in the bit line direction (the y-direction) and is in contact with second conductive layer 502B and second high-k dielectric layers 612B. For example, the liner layer used for protecting second high-k dielectric layer 612B may be fully removed when forming interconnect line 206B, so that there is no remainder (liner plugs) disposed between interconnect line 206B of second contact structure 106B and second high-k dielectric layers 612B in the bit line direction (the y-direction).

It is understood that liner plugs 702 may be formed at more than one level of stack structure 201. For example, although not shown, liner plugs may be formed between interconnect line of a third contact structure and the corresponding high-k dielectric layers in the bit line direction (the y-direction) as well. The interconnect line of the third contact structure may be between interconnect line 206A and interconnect line 206B in the vertical direction (the z-direction), and the lateral distance between the contact structure opening of the third contact structure and conductive portion 105 may be between those of first and second contact structures 106A and 106B. The liner plugs between the interconnect line of the third contact structure and the corresponding high-k dielectric layers may have a different length (e.g., in the y-direction) from liner plugs 702, such as being shorter than liner plugs 702. It is also understood that in some examples, liner plugs may not be formed in more than one level of stack structure 201. In other words, multiple liner layers protecting multiple high-k dielectric layers 612 at multiple levels of stack structure 201 may be fully removed when forming interconnect lines 206.

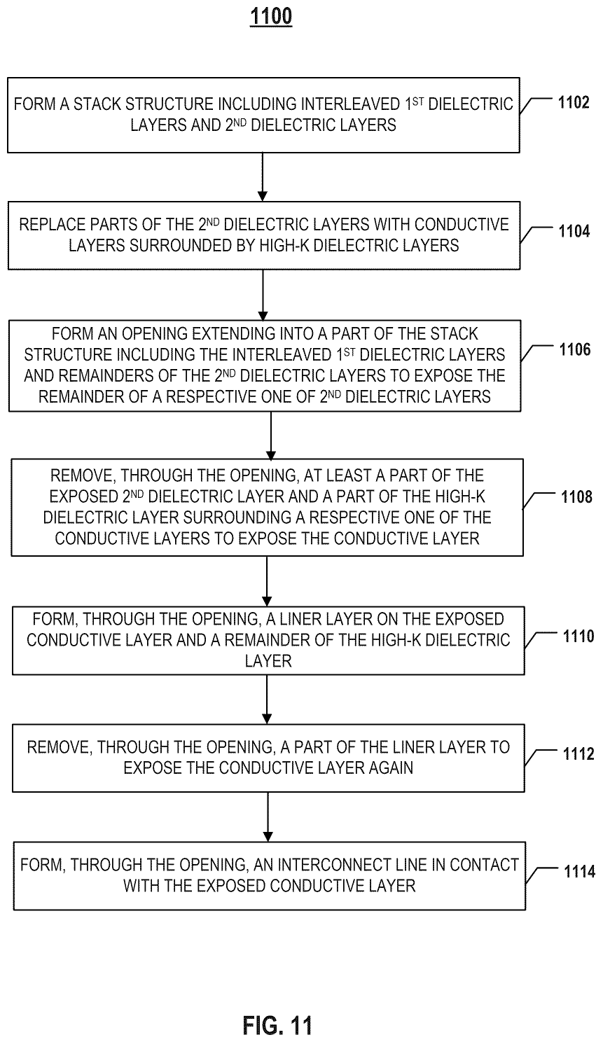

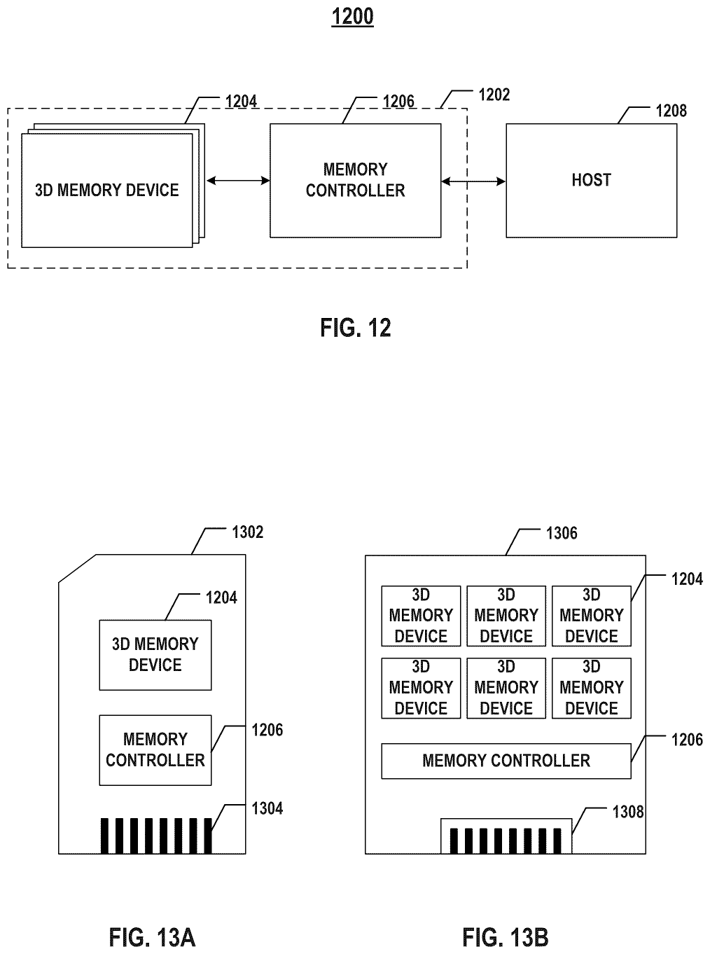

FIG. 12 illustrates a block diagram of an exemplary system 1200 having a 3D memory device, according to some aspects of the present disclosure. System 1200 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 12, system 1200 can include a host 1208 and a memory system 1202 having one or more 3D memory devices 1204 and a memory controller 1206. Host 1208 can be a processor of an electronic device, such as a central processing unit (CPU), or a system-on-chip (SoC), such as an application processor (AP). Host 1208 can be configured to send or receive data to or from 3D memory devices 1204.

3D memory device 1204 can be any 3D memory device having contact structures disclosed herein, such as 3D memory device 100 depicted in FIGS. 1-7 and 8A-8C. In some implementations, each 3D memory device 1204 includes a NAND Flash memory. Consistent with the scope of the present disclosure, the contact structures can replace the staircase structures and word line contacts to achieve word line pick-up/fan-out functions, thereby reducing the manufacturing cost and simplifying the fabrication process. In some implementations, each 3D memory device 1204 further includes liner plugs between the interconnect line of at least one contact structure and the corresponding high-k dielectric layer in the bit line direction.

Memory controller 1206 (a.k.a., a controller circuit) is coupled to 3D memory device 1204 and host 1208 and is configured to control 3D memory device 1204, according to some implementations. For example, memory controller 1206 may be configured to operate the plurality of channel structures via the conductive layers (e.g., word lines and gate lines). Memory controller 1206 can manage the data stored in 3D memory device 1204 and communicate with host 1208. In some implementations, memory controller 1206 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1206 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1206 can be configured to control operations of 3D memory device 1204, such as read, erase, and program operations. Memory controller 1206 can also be configured to manage various functions with respect to the data stored or to be stored in 3D memory device 1204 including, but not limited to bad-block management, garbage collection, logical-to-physical address conversion, wear leveling, etc. In some implementations, memory controller 1206 is further configured to process error correction codes (ECCs) with respect to the data read from or written to 3D memory device 1204. Any other suitable functions may be performed by memory controller 1206 as well, for example, formatting 3D memory device 1204. Memory controller 1206 can communicate with an external device (e.g., host 1208) according to a particular communication protocol. For example, memory controller 1206 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1206 and one or more 3D memory devices 1204 can be integrated into various types of storage devices, for example, be included in the same package, such as a universal Flash storage (UFS) package or an eMMC package. That is, memory system 1202 can be implemented and packaged into different types of end electronic products. In one example as shown in FIG. 13A, memory controller 1206 and a single 3D memory device 1204 may be integrated into a memory card 1302. Memory card 1302 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1302 can further include a memory card connector 1304 electrically coupling memory card 1302 with a host (e.g., host 1208 in FIG. 12). In another example as shown in FIG. 13B, memory controller 1206 and multiple 3D memory devices 1204 may be integrated into an SSD 1306. SSD 1306 can further include an SSD connector 1308 electrically coupling SSD 1306 with a host (e.g., host 1208 in FIG. 12). In some implementations, the storage capacity and/or the operation speed of SSD 1306 is greater than those of memory card 1302.

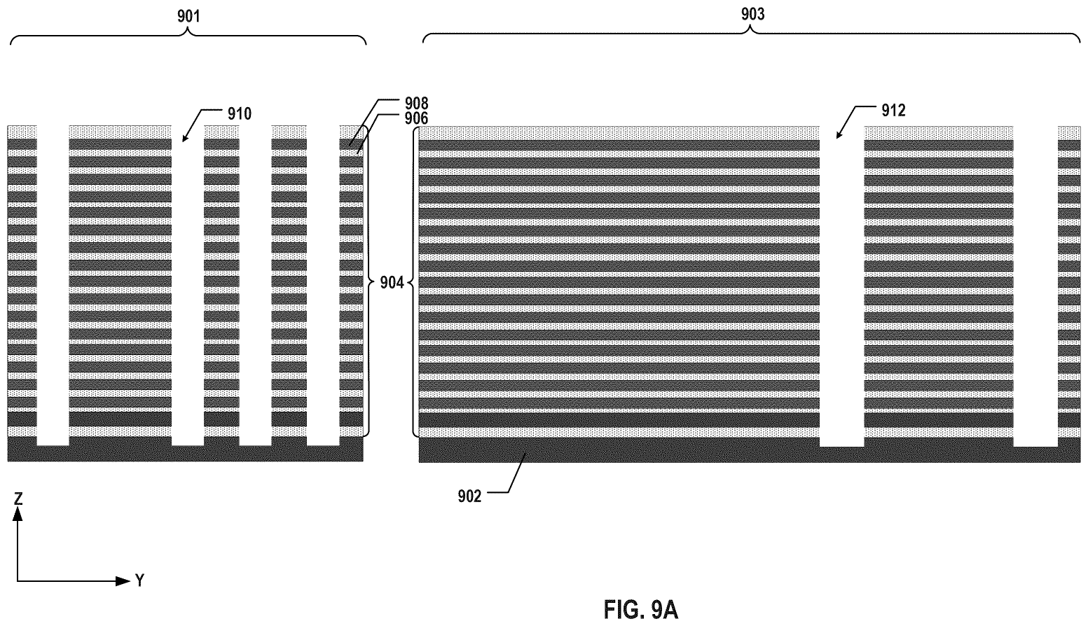

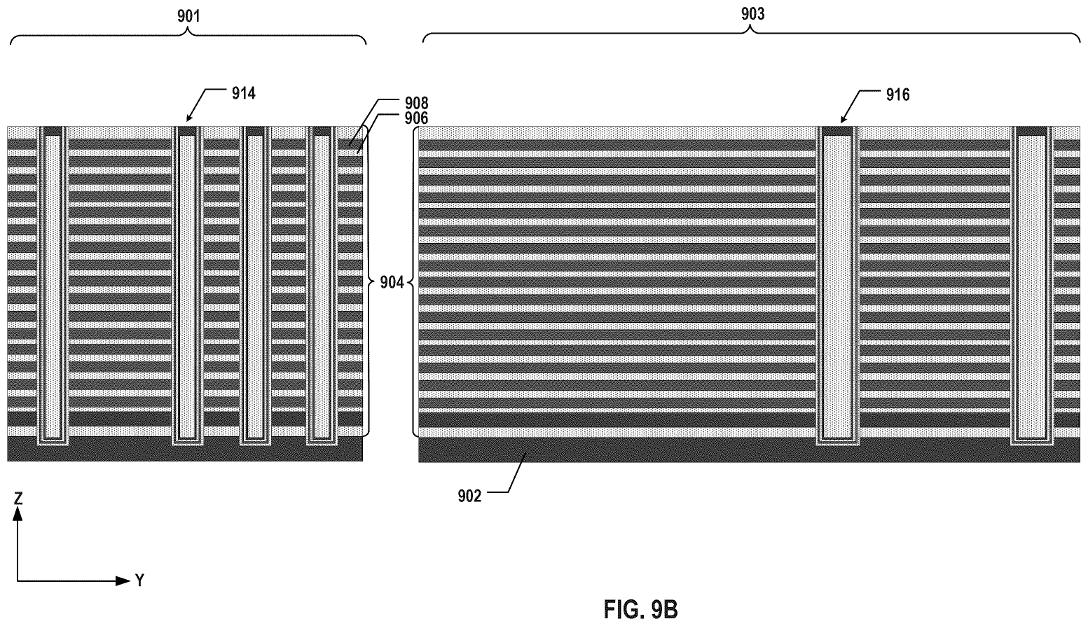

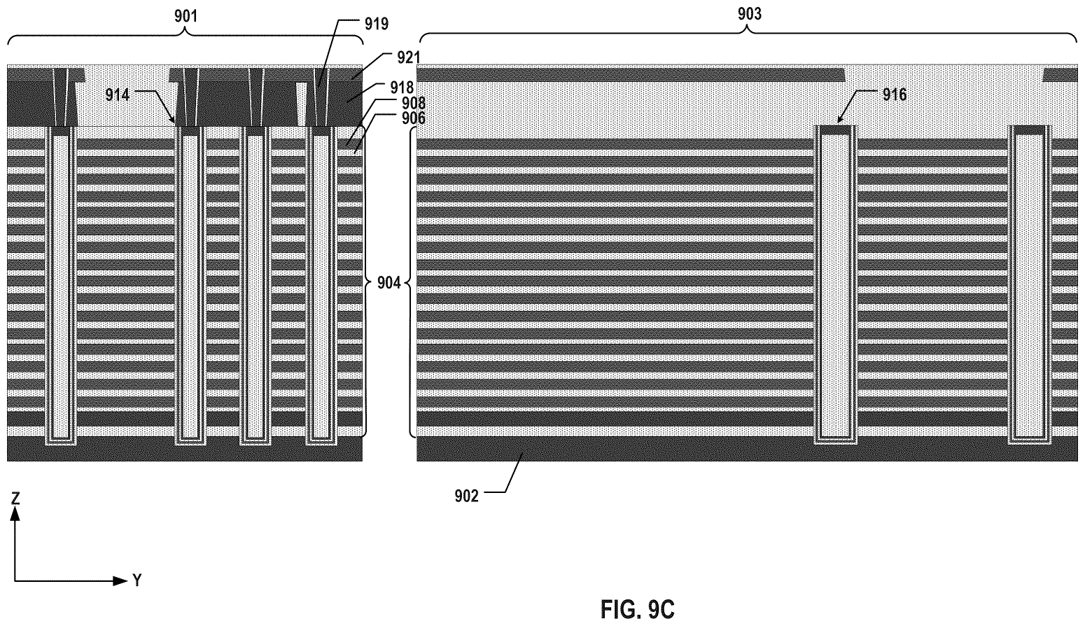

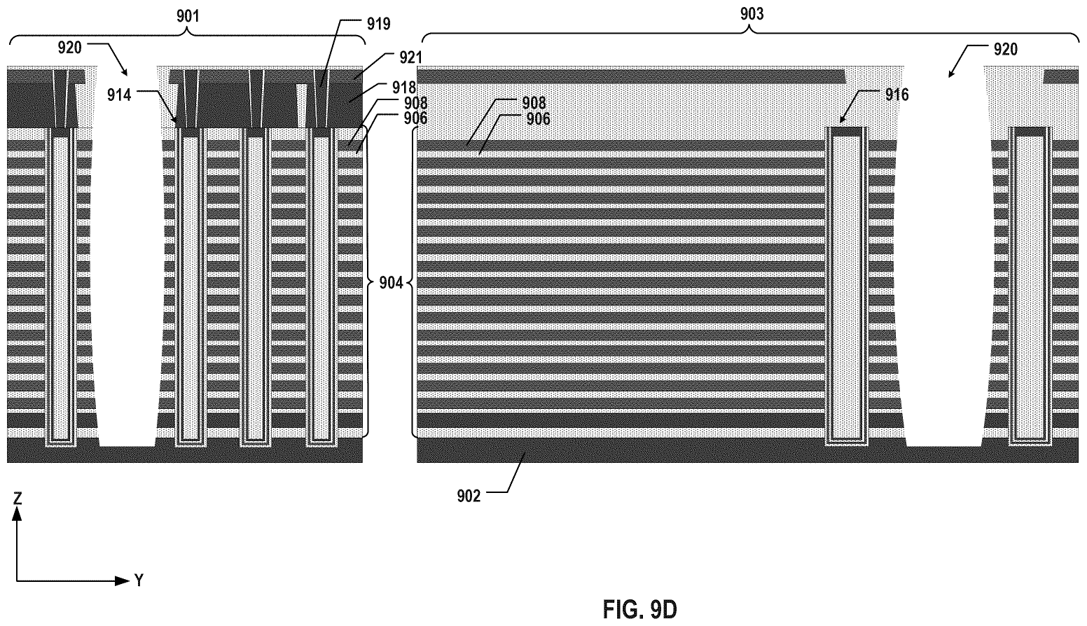

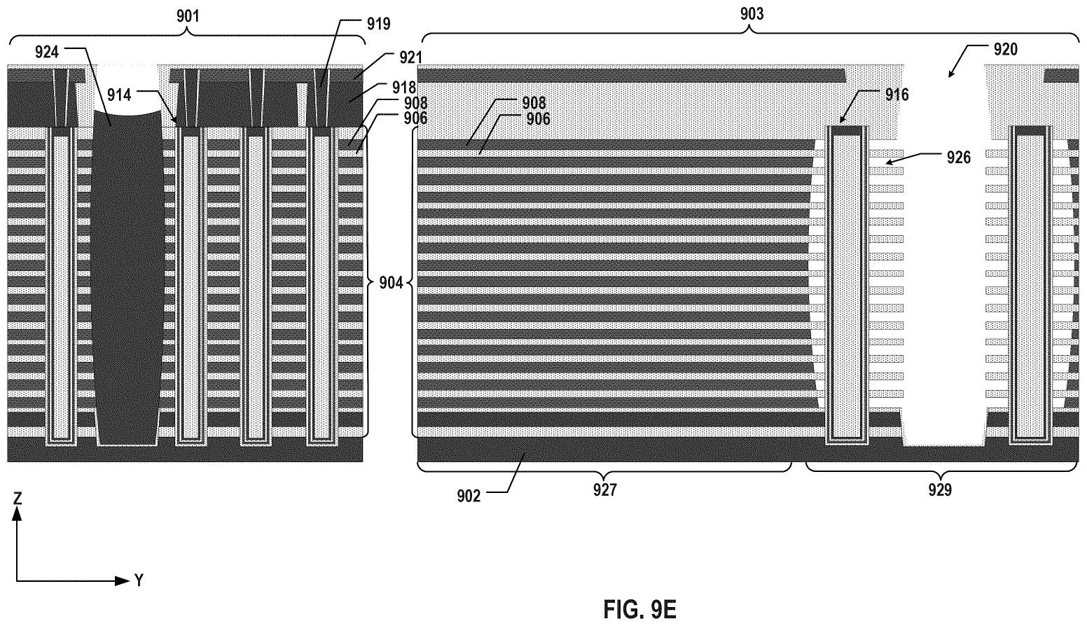

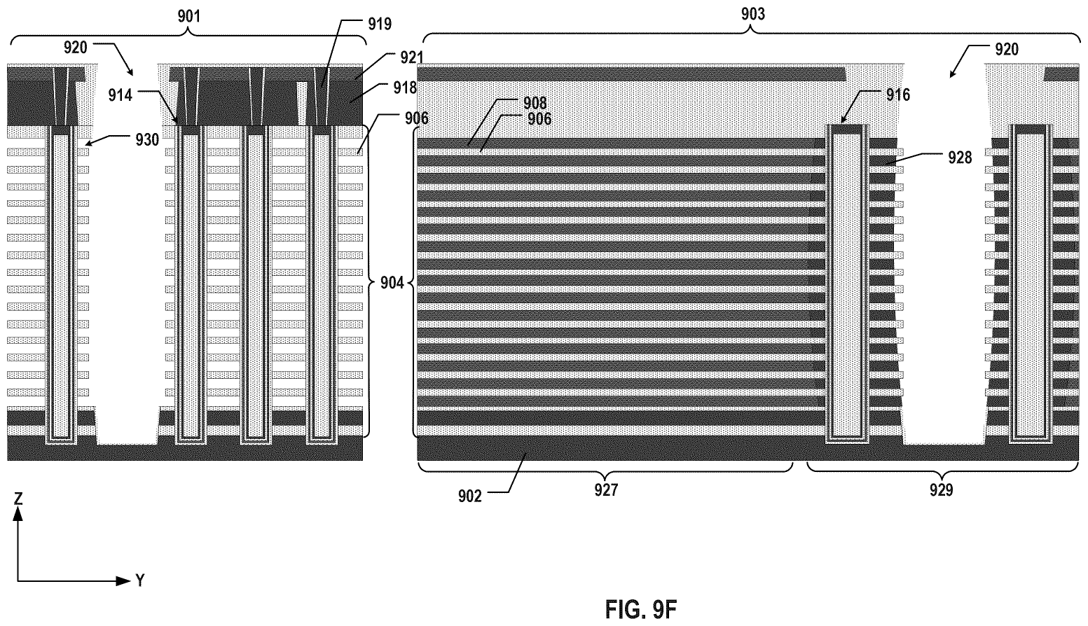

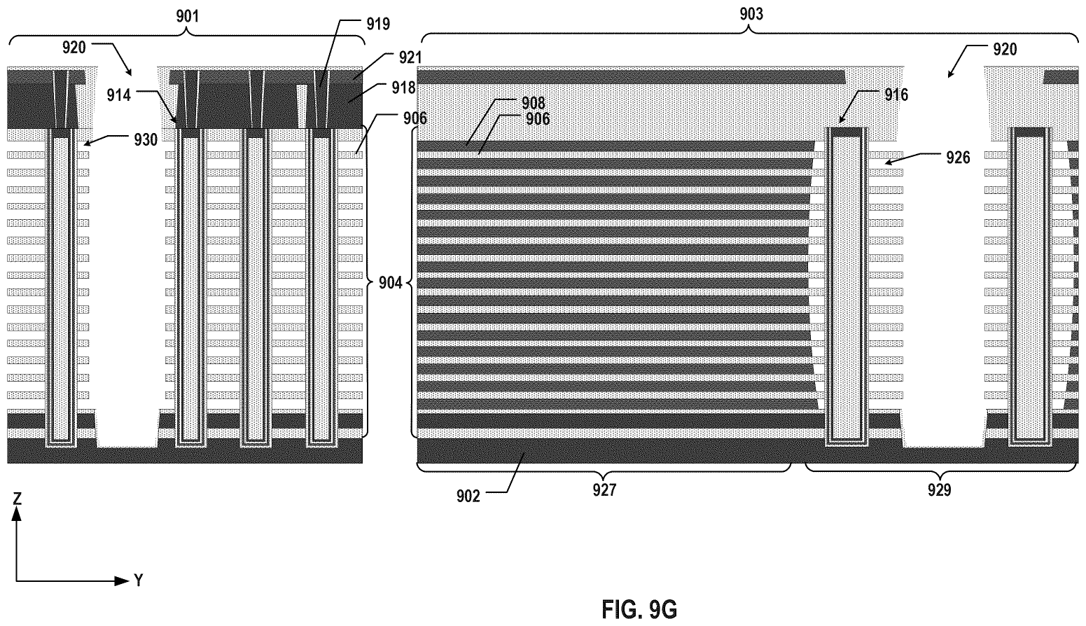

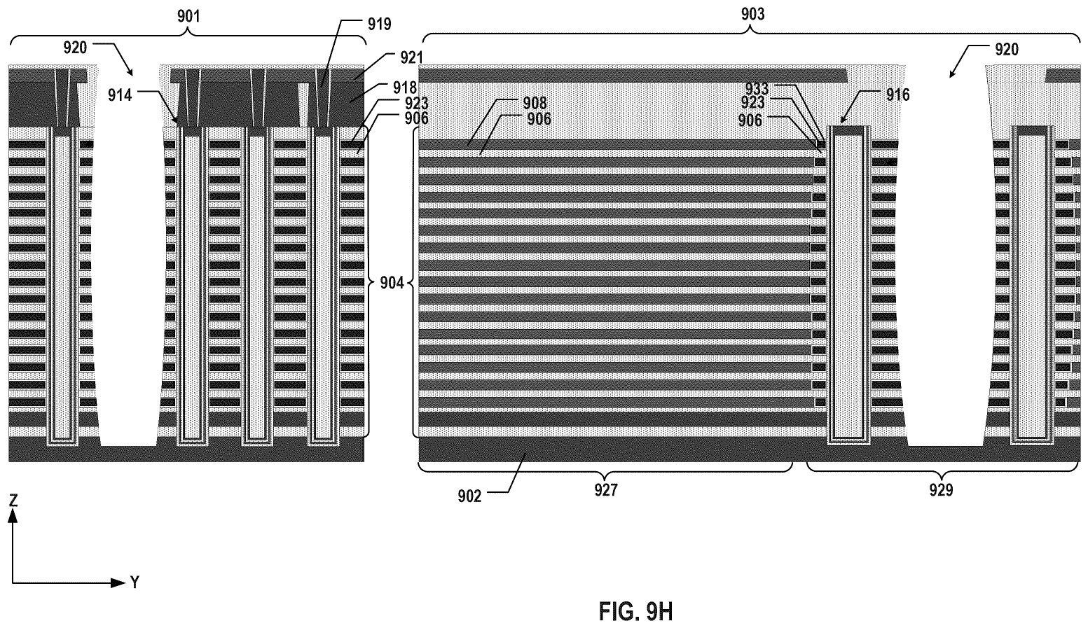

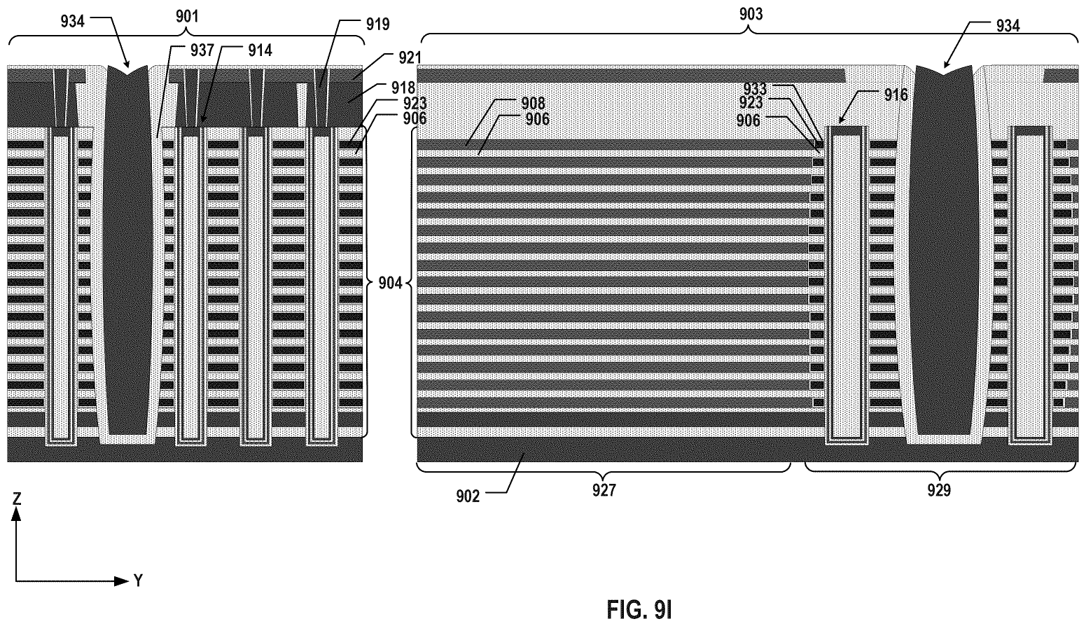

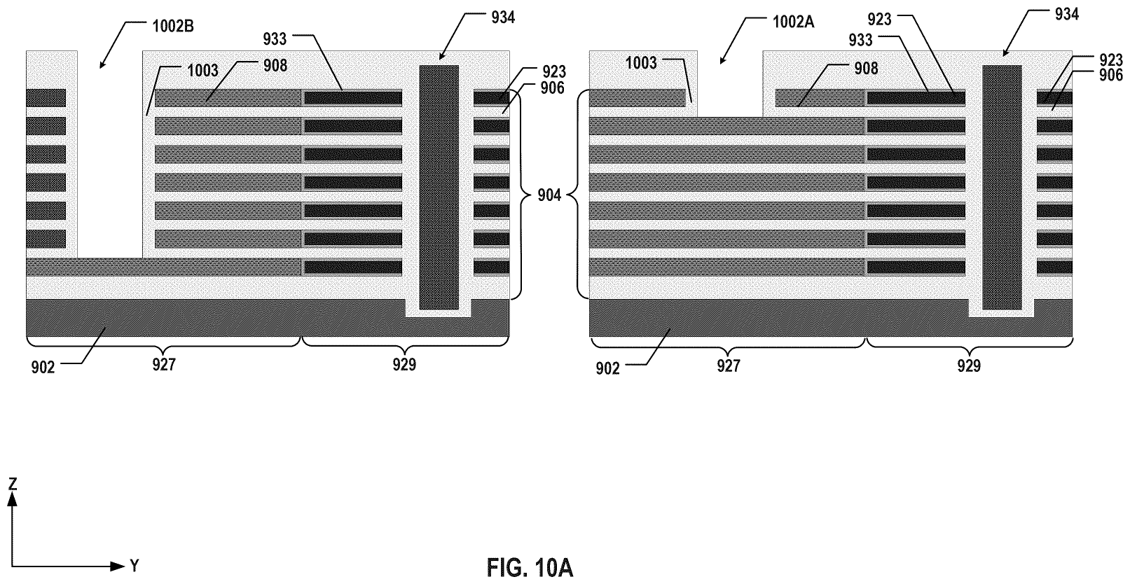

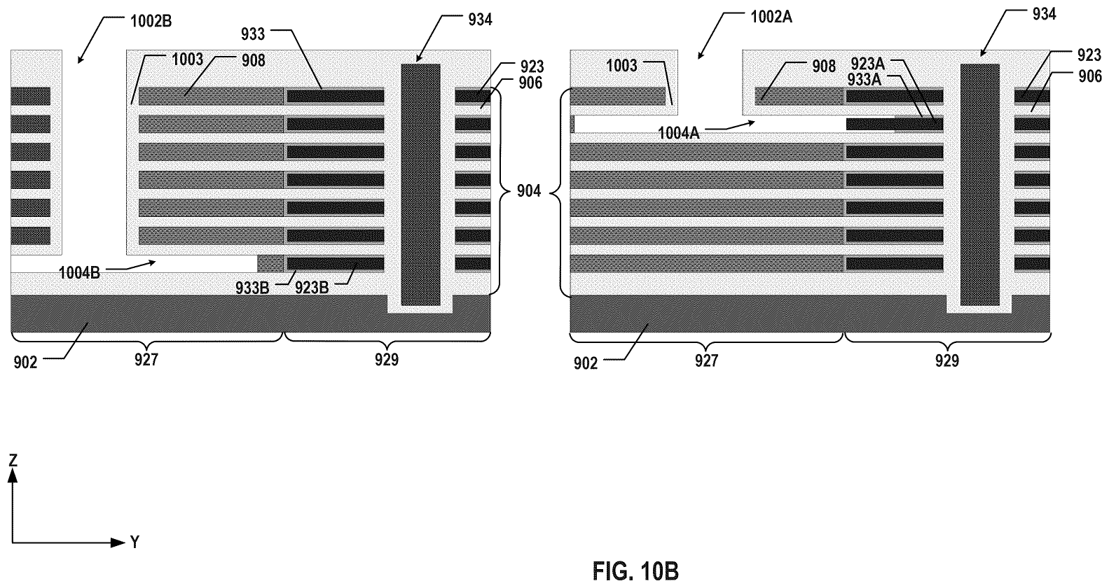

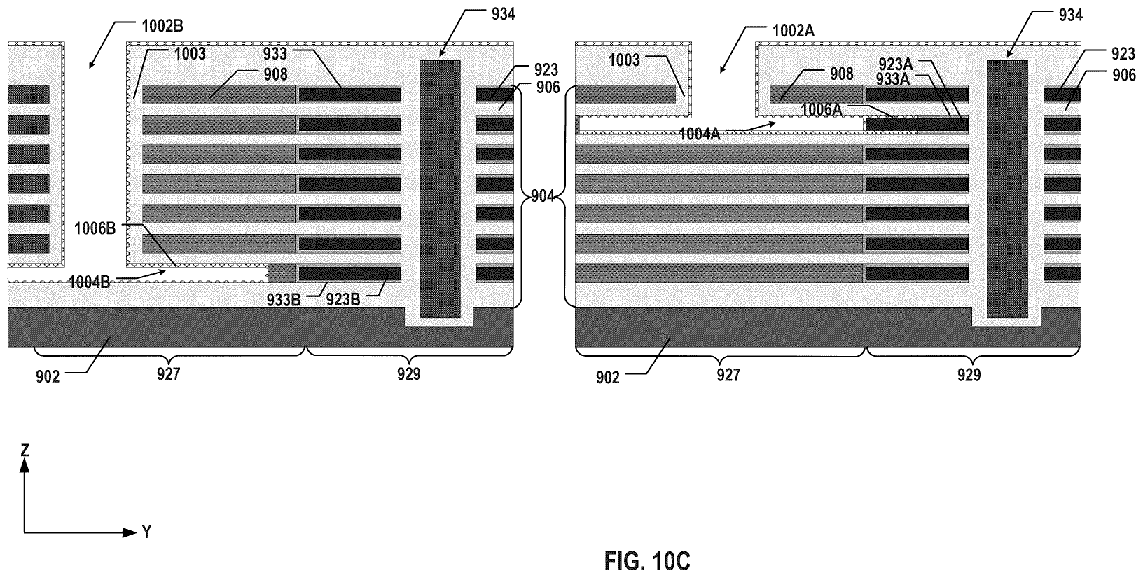

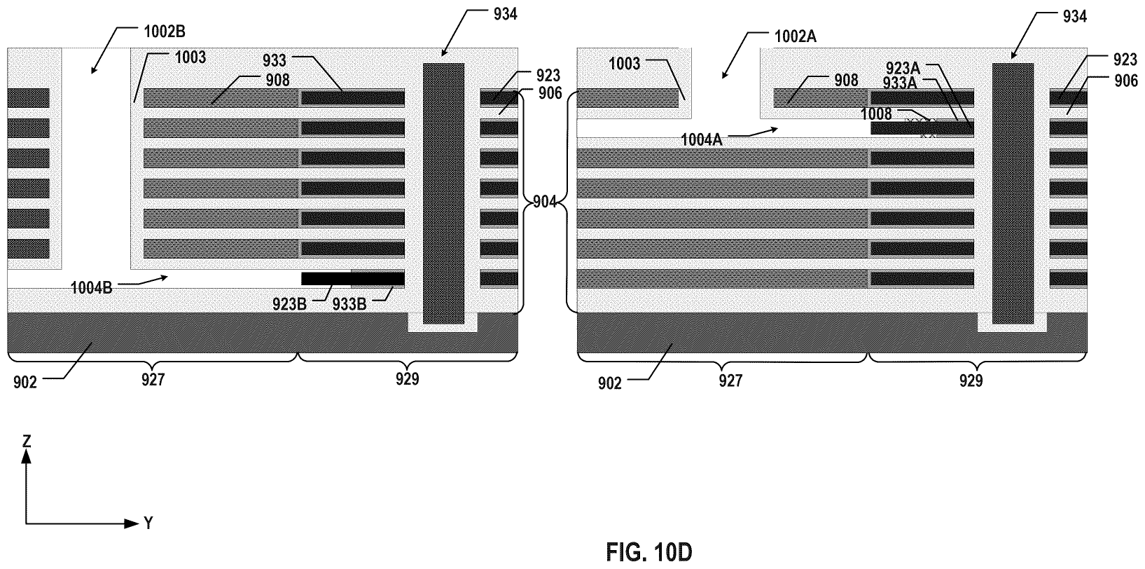

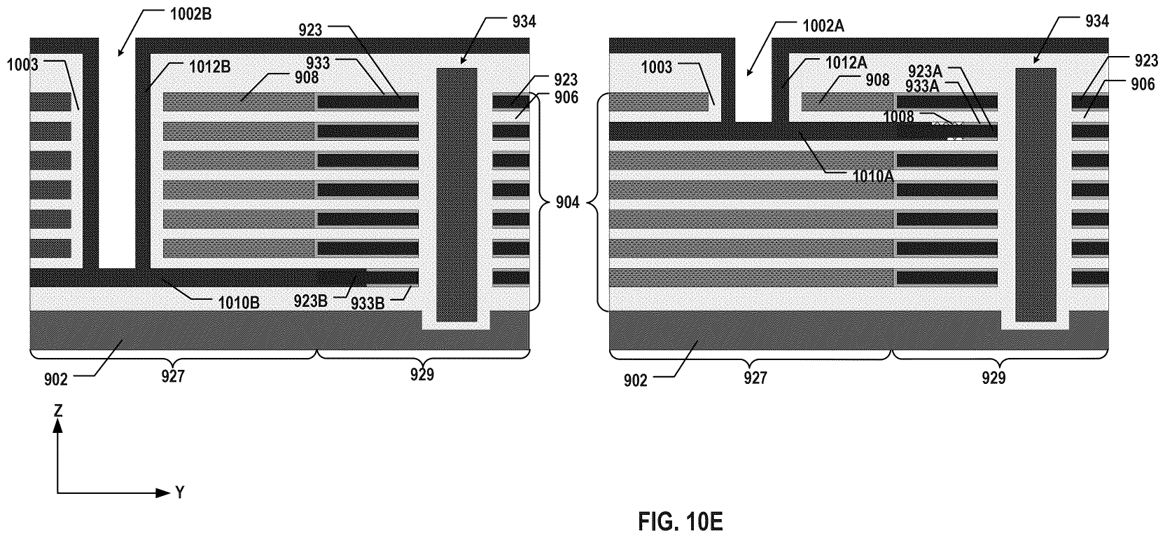

FIGS. 9A-9G illustrate a fabrication process for forming a 3D memory device before forming contact structures, according to some aspects of the present disclosure. FIGS. 10A-10E illustrate a fabrication process for forming contact structures of a 3D memory device, according to some aspects of the present disclosure. FIG. 11 illustrates a flowchart of a method 1100 for forming an exemplary 3D memory device having contact structures, according to some implementations of the present disclosure. Examples of the 3D memory device depicted in FIGS. 9A-9G, 10A-10E, and 11 include 3D memory devices 100 depicted in FIGS. 1-7 and 8A-8C. FIGS. 9A-9G, 10A-10E, and 11 will be described together. It is understood that the operations shown in method 1100 are not exhaustive and that other operations can be performed as well before, after, or between any of the illustrated operations. Further, some of the operations may be performed simultaneously, or in a different order than shown in FIG. 11.

Referring to FIG. 11, method 1100 starts at operation 1102, in which a stack structure including interleaved first dielectric layers and second dielectric layers is formed. The first dielectric layers can include silicon oxide, and the second dielectric layers can include silicon nitride. In some implementations, to form the stack structure, the first dielectric layers and the second dielectric layers are alternatingly deposited above a substrate. The substrate can be a silicon substrate.

As illustrated in FIG. 9A, a stack structure 904 including multiple pairs of a first dielectric layer 906 and a second dielectric layer 908 (a.k.a., a stack sacrificial layer) is formed above a silicon substrate 902. Stack structure 904 includes vertically interleaved first dielectric layers 906 and second dielectric layers 908, according to some implementations. First and second dielectric layers 906 and 908 can be alternatingly deposited above silicon substrate 902 to form stack structure 904. In some implementations, each first dielectric layer 906 includes a layer of silicon oxide, and each second dielectric layer 908 includes a layer of silicon nitride. Stack structure 904 can be formed by one or more thin film deposition processes including, but not limited to, chemical vapor deposition (CVD), physical vapor deposition (PVD), atomic layer deposition (ALD), or any combination thereof.

In some implementations, channel structures extending through the first dielectric layers and the second dielectric layers are formed in a first region of the stack structure. In some implementations, to form the channel structure, a channel hole extending vertically through the stack structure is formed, and a memory layer and a channel layer are sequentially formed over sidewalls of the channel hole. In some implementations, dummy channel structures extending through the first dielectric layers and the second dielectric layers are formed in a second region of the stack structure in the same process of forming the channel structures. That is, channel structures and dummy channel structures can be simultaneously formed through the first dielectric layers and the second dielectric layers in the first region and the second region of the stack structure, respectively.

As illustrated in FIG. 9B, channel structures 914 can be formed in a core array region 901 of stack structure 904, for example, corresponding to core array region 101 of stack structure 201 in FIGS. 1-3. To form each channel structure 914, as illustrated in FIG. 9A, a channel hole 910, which is an opening extending vertically through stack structure 904, can be formed first in core array region 901. In some implementations, a plurality of openings are formed, such that each opening becomes the location for growing an individual channel structure 914 in the later process. In some implementations, fabrication processes for forming channel hole 910 of channel structure 914 include wet etching and/or dry etching, such as deep-ion reactive etching (DRIE).

As illustrated in FIG. 9B, a memory layer (including a blocking layer, a storage layer, and a tunneling layer) and a channel layer are sequentially formed in this order along sidewalls and the bottom surface of channel hole 910, for example, corresponding to the example shown in FIG. 6. In some implementations, the memory layer is first deposited along the sidewalls and bottom surface of channel hole 910, and the semiconductor channel is then deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are subsequently deposited to form the memory layer and the channel layer of channel structure 914.

In some implementations, as illustrated in FIG. 9B, dummy channel structures 916 can be formed in a word line pick-up region 903 of stack structure 904, for example, corresponding to word line pick-up region 103 of stack structure 201 in FIGS. 1-3, in the same process of forming channel structures 914. To form each dummy channel structure 916, as illustrated in FIG. 9A, a dummy channel hole 912, which is another opening extending vertically through stack structure 904, can be formed in word line pick-up region 903 simultaneously as channel hole 910 by the same wet etching and/or dry etching, such as DRIE. As illustrated in FIG. 9B, dummy channel structure 916 can then be formed simultaneously as channel structure 914 by the same thin film deposition processes, such as ALD, CVD, PVD, any other suitable processes, or any combination thereof that deposit a memory layer (including a blocking layer, a storage layer, and a tunneling layer) and a channel layer. It is understood that in some examples, dummy channel structures 916 may be formed in a separate process from channel structures 914.

As illustrated in FIG. 9C, a DSG layer 918 and a stop layer 921 are formed on core array region 901 of stack structure 904. DSG layer 918 can include a semiconductor layer, such as a polysilicon layer, and stop layer 921 can include a silicon nitride layer. DSG layer 918 and stop layer 921 can be sequentially deposited on core array region 901, but not on word line pick-up region 903, of stack structure 904 using one or more thin film deposition processes including, but not limited to, CVD, PVD, ALD, or any combination thereof. DSG channel structures 919 can be formed extending vertically through DSG layer 918 and stop layer 921 to be in contact with the upper ends of channel structures 914, but not dummy channel structures 916, as shown in FIG. 9C. To form DSG channel structures 919, DSG holes can be etched through DSG layer 918 and stop layer 921 to expose the upper ends of channel structures 914, respectively, and a spacer (e.g., having silicon oxide) and a semiconductor layer (e.g., having polysilicon) can be sequentially deposited into the DSG holes using one or more thin film deposition processes, such as CVD, PVD, ALD, or any combination thereof, to fill the DSG holes.

Method 1100 proceeds to operation 1104, as illustrated in FIG. 11, in which parts of the second dielectric layers are replaced with conductive layers surrounded by high-k dielectric layers, for example, by a gate replacement process. In some implementations, all the second dielectric layers in the first region and the parts of the second dielectric layers in the second region of the stack structure are replaced with the conductive layers surrounded by the high-k dielectric layers. The conductive layers can include a metal, such as tungsten, and the high-k dielectric layers can include aluminum oxide.

In some implementations, to replace all the second dielectric layers in the first region and the parts of the second dielectric layers in the second region of the stack structure with the conductive layers surrounded by the high-k dielectric layers, a slit extending through the first dielectric layers and the second dielectric layers and across the first region and the second region of the stack structure is formed.

As illustrated in FIG. 9D, a slit 920 is an opening that extends vertically through stop layer 921, DSG layer 918, and first dielectric layers 906 and second dielectric layers 908 (a.k.a., stack sacrificial layers) of stack structure 904 until silicon substrate 902. Slit 920 can also extend laterally across core array region 901 and word line pick-up region 903 in the x-direction (the word line direction), for example, corresponding to slit structure 108 in FIG. 1. In some implementations, fabrication processes for forming slit 920 include wet etching and/or dry etching, such as DRIE, of first dielectric layers 906 and second dielectric layers 908. The etching process through stack structure 904 may not stop at the top surface of silicon substrate 902 and may continue to etch part of silicon substrate 902 to ensure that slit 920 extends vertically all the way through all first dielectric layers 906 and second dielectric layers 908 of stack structure 904.

In some implementations, to replace all the second dielectric layers in the first region and the parts of the second dielectric layers in the second region of the stack structure with the conductive layers surrounded by the high-k dielectric layers, the slit in the first region of the stack structure is covered. As illustrated in FIG. 9E, the part of slit 920 in core array region 901 is covered by a sacrificial layer 924. In some implementations, sacrificial layer 924 that is different from first dielectric layers 906 and second dielectric layers 908, such as a polysilicon layer or a carbon layer, is deposited into slit 920 using one or more thin film deposition processes, such as CVD, PVD, ALD, or any combination thereof, to at least partially fill slit 920 (covering the exposed first dielectric layers 906 and second dielectric layers 908 in slit 920). Sacrificial layer 924 can then be patterned using lithography and wet etching and/or dry etching to remove the part of sacrificial layer 924 in word line pick-up region 903, leaving only the part of sacrificial layer 924 in core array region 901 to cover only the part of slit 920 in core array region 901.

In some implementations, to replace all the second dielectric layers in the first region and the parts of the second dielectric layers in the second region of the stack structure with the conductive layers surrounded by the high-k dielectric layers, the parts of the second dielectric layers in the second region of the stack structure are removed through the slit in the second region of the stack structure. As illustrated in FIG. 9E, parts of second dielectric layers 908 in a conductive portion 929 of word line pick-up region 903 are removed by wet etching to form lateral recesses 926, leaving the remainders of second dielectric layers 908 in a dielectric portion 927 of word line pick-up region 903 intact. In some implementations, the parts of second dielectric layers 908 are wet etched by applying a wet etchant through the part of slit 920 in word line pick-up region 903 that is uncovered by sacrificial layer 924, creating lateral recesses 926 interleaved between first dielectric layers 906. The wet etchant can include phosphoric acid for etching second dielectric layers 908 including silicon nitride. In some implementations, the etching rate and/or etching time are controlled to remove only the parts of second dielectric layers 908 in conductive portion 929, leaving the remainders of second dielectric layers 908 intact in dielectric portion 927. By controlling the etching time, the wet etchant does not travel all the way to completely remove second dielectric layers 908 in word line pick-up region 903, thereby defining two portions in word line pick-up region 903—dielectric portion 909 in which second dielectric layers 908 are removed, and dielectric portion 927 in which second dielectric layers 908 remain. As illustrated in FIG. 9E, since the part of slit 920 in core array region 901 is covered by sacrificial layer 924 that is resistant to the etchant for removing second dielectric layers 908, all second dielectric layers 908 remain intact in core array region 901.

In some implementations, to replace all the second dielectric layers in the first region and the parts of the second dielectric layers in the second region of the stack structure with the conductive layers surrounded by the high-k dielectric layers, the slit in the first region of the stack structure is opened. As illustrated in FIG. 9F, the part of slit 920 in core array region 901 is re-opened by removing sacrificial layer 924 (shown in FIG. 9E) to expose first dielectric layers 906 and second dielectric layers 908 (shown in FIG. 9E). In some implementations, sacrificial layer 924 is selectively etched away from the part of slit 920 in core array region 901, for example, using potassium hydroxide (KOH) for etching sacrificial layer 924 having polysilicon, to open the part of slit 920 in core array region 901.

In some implementations, to replace all the second dielectric layers in the first region and the parts of the second dielectric layers in the second region of the stack structure with the conductive layers surrounded by the high-k dielectric layers, the slit in the second region of the stack structure is covered. As illustrated in FIG. 9F, lateral recesses 926 (shown in FIG. 9E) and the part of slit 920 in word line pick-up region 903 are covered by a sacrificial layer 928. In some implementations, sacrificial layer 928 that is different from first dielectric layers 906 and second dielectric layers 908, such as a polysilicon layer or a carbon layer, is deposited into lateral recesses 926 and slit 920 using one or more thin film deposition processes, such as CVD, PVD, ALD, or any combination thereof, to at least partially fill slit 920 (covering the exposed first dielectric layers 906 and second dielectric layers 908). Sacrificial layer 928 can then be patterned using lithography and wet etching and/or dry etching to remove the part of sacrificial layer 928 in core array region 901, leaving only the part of sacrificial layer 928 in word line pick-up region 903 to cover only lateral recesses 926 and the part of slit 920 in word line pick-up region 903, but not in core array region 901. It is understood that lateral recesses 926 may be considered as parts of slit 920 in word line pick-up region 903. Thus, even if only lateral recesses 926 are fully or partially filled by sacrificial layer 928 (e.g., as shown in FIG. 9F), the part of slit 920 in word line pick-up region 903 may still be considered as being covered.

In some implementations, to replace all the second dielectric layers in the first region and the parts of the second dielectric layers in the second region of the stack structure with the conductive layers surrounded by the high-k dielectric layers, all the second dielectric layers in the first region of the stack structure are removed through the slit in the first region of the stack structure. As illustrated in FIG. 9F, all second dielectric layers 908 (as shown in FIG. 9E) in core array region 901 are fully removed by wet etching to form lateral recesses 930. In some implementations, second dielectric layers 908 are wet etched by applying a wet etchant through the part of slit 920 in core array region 901 that is uncovered by sacrificial layer 928, creating lateral recesses 930 interleaved between first dielectric layers 906. The wet etchant can include phosphoric acid for etching second dielectric layers 908 including silicon nitride. In some implementations, the etching rate and/or etching time are controlled to ensure that all second dielectric layers 908 in core array region 901 are completely etched away. As illustrated in FIG. 9F, since the part of slit 920 in word line pick-up region 903 is covered by sacrificial layer 928 that is resistant to the etchant for removing second dielectric layers 908, the remainders of second dielectric layers 908 in dielectric portion 927 of word line pick-up region 903 remain intact.

In some implementations, to replace all the second dielectric layers in the first region and the parts of the second dielectric layers in the second region of the stack structure with the conductive layers surrounded by the high-k dielectric layers, the slit in the second region of the stack structure is opened. As illustrated in FIG. 9G, the part of slit 920 in word line pick-up region 903 is re-opened by removing sacrificial layer 928 (shown in FIG. 9F) to expose first dielectric layers 906 and the remainders of second dielectric layers 908 in word line pick-up region 903. In some implementations, sacrificial layer 928 is selectively etched away from the part of slit 920 in word line pick-up region 903, for example, using KOH for etching sacrificial layer 928 having polysilicon, to open the part of slit 920 (and lateral recesses 926) in word line pick-up region 903.

In some implementations, to replace all the second dielectric layers in the first region and the parts of the second dielectric layers in the second region of the stack structure with the conductive layers surrounded by the high-k dielectric layers, the high-k dielectric layers and the conductive layers are sequentially deposited through the slit in the first region and the second region of the stack structure. As illustrated in FIG. 9H, high-k dielectric layers 933 and conductive layers 923 are sequentially deposited into lateral recesses 930 and 926 (shown in FIG. 9G) in core array region 901 and conductive portion 929 of word line pick-up region 903 through slit 920, such that conductive layers 923 are deposited on and surrounded by high-k dielectric layers 933. High-k dielectric layers 933, such as aluminum oxide layers, and conductive layers 923, such as metal layers, can be sequentially deposited using one or more thin film deposition processes, such as ALD, CVD, PVD, any other suitable processes, or any combination thereof.

As described above, the removal of second dielectric layers 908 (stack sacrificial layers, e.g., having silicon nitride) can be performed separately in core array region 901 and word line pick-up region 903 by partially covering slit 920 in core array region 901 or word line pick-up region 903 to allow second dielectric layers 908 to be removed at different scopes (e.g., fully removal in core array region 901 and partial removal in word line pick-up region 903). In the gate replacement process described above with respect to FIGS. 9E-9H, the removal of second dielectric layers 908 is performed first in word line pick-up region 903, and then in core array region 901. It is understood that in another gate replacement process, the removal of second dielectric layers 908 may be performed first in core array region 901, and then in word line pick-up region 903 (not shown).

In any event, after any suitable gate replacement process, stack structure 904 can be redefined into two stack structures—a conductive stack structure including interleaved first dielectric layers 906 and conductive layers 923 surrounded by high-k dielectric layers 933 in core array region 901 as well as in conductive portion 929 of word line pick-up region 903, and a dielectric stack structure including interleaved first dielectric layers 906 and the remainders of second dielectric layers 908 in dielectric portion 927 of word line pick-up region 903. That is, all second dielectric layers 908 in core array region 901 and parts of second dielectric layers 908 in word line pick-up region 903 of stack structure 904 are replaced with conductive layers 923 surrounded by high-k dielectric layers 933, according to some implementations. Moreover, in some examples, since the dielectric stack structure in dielectric portion 927 of word line pick-up region 903 remains intact during the gate replacement process (without removal of the remainders of second dielectric layers 908 therein), dummy channel structures 916 may not need to be formed in dielectric portion 927 of word line pick-up region 903 to provide mechanical support when removing second dielectric layer 908.

In some implementations, a slit spacer is formed in the slit. As illustrated in FIG. 9I, a slit spacer 937 is formed in slit 920 (shown in FIG. 9H) to form a slit structure 934 extending vertically through interleaved conductive layers 923 and first dielectric layers 906 of stack structure 904 and laterally across core array region 901 and conductive portion 929 of word line pick-up region 903. Slit spacer 937 can be formed by depositing dielectrics into slit 920 using one or more thin film deposition processes, such as ALD, CVD, PVD, any other suitable processes, or any combination thereof. In some implementations, conductive materials (e.g., as a source contact) are deposited into slit 920 after slit spacer 937 as part of slit structure 934.

Referring back to FIG. 11, method 1100 proceeds to operation 1106, as illustrated in FIG. 11, in which an opening extending into a part of the stack structure including the interleaved first dielectric layers and remainders of the second dielectric layers is formed to expose the remainder of a respective one of second dielectric layers. In some implementations, another opening extending into the part of the stack structure is formed to expose the remainder of a respective another one of second dielectric layers. The opening and the another opening can be formed at different depths. In some implementations, the opening is formed at a lower depth than the another opening.

As illustrated in FIG. 10A, a first opening 1002A and a second opening 1002B extend vertically through different numbers of pairs of first and second dielectric layers 906 and 908 of the dielectric stack structure in dielectric portion 927 of word line pick-up region 903, stopping at different depths, for example, corresponding to the example shown in FIG. 7. As shown in FIG. 10A, second opening 1002B can extend further into the dielectric stack structure in dielectric portion 927 in the vertical direction (the z-direction) and penetrate more pairs of first and second dielectric layers 906 and 908 than first opening 1002A. In other words, second opening 1002B can have a larger depth than first opening 1002A. Consequently, in some implementations, first opening 1002A is closer to conductive portion 929 of word line pick-up region 903 than second opening 1002B.

First and second openings 1002A and 1002B can be formed using a chopping process. It is understood that although two openings 1002A and 1002B are illustrated in FIG. 10A, the number of openings may be more than two in other examples. In other words, a plurality of openings can be formed at different depths using a chopping process. As used herein, a “chopping” process is a process that increases the depth of one or more openings extending through a dielectric stack structure including interleaved first and second dielectric layers by a plurality of etching cycles. Each etch cycle can include one or more dry etch and/or wet etch processes that etch one pair of first and second dielectric layers, i.e., reducing the depth by one dielectric layer pair. The purpose of the chopping process is to make the openings at different depths. Accordingly, depending on the number of openings, a certain number of chopping processes, along with a number of chopping masks, may be needed. It is understood that the number of chopping masks, the sequence of the chopping masks, the design (e.g., the number and pattern of openings) of each chopping mask, and/or the reduced depth by each chopping process (e.g., the number of etching cycles) may affect the specific depth of each opening after the chopping process.

It is understood that the chopping process can be more easily performed through a dielectric stack structure including interleaved first and second dielectric layers (e.g., silicon oxide and silicon nitride), as opposed to a conductive stack structure including interleaved conductive layers and dielectric layers (e.g., metal and silicon oxide) due to the etching properties of the different materials. Thus, the dielectric stack structure remains after the gate replacement process in dielectric portion 927 of word line pick-up region 903 is suitable for forming first and second openings 1002A and 1002B for word line pick-up structures at different depths using the chopping process, according to some implementations.

In some implementations, a spacer is formed on sidewalls and a bottom of each of the openings. As illustrated in FIG. 10A, a contact spacer 1003 is formed on the sidewalls and the bottom surface of each of first and second openings 1002A and 1002B, thereby covering first dielectric layers 906 and second dielectric layers 908 exposed from the sidewalls of first and second openings 1002A and 1002B. In some implementations, contact spacer 1003 is formed by depositing dielectric materials, such as silicon oxide, using one or more thin film deposition processes, such as ALD, CVD, PVD, any other suitable processes, or any combination thereof, over the sidewalls and the bottom surfaces of first and second openings 1002A and 1002B.

In some implementations, the spacer on the bottom of each of the openings is removed to expose the respective part of the remainder of the second dielectric layer. As illustrated in FIG. 10A, the part of contact spacer 1003 on the bottom surface of each of first and second openings 1002A and 1002B is removed, for example, by dry etching, to expose part of second dielectric layer 908 in dielectric portion 927 of word line pick-up region 903. In some implementations, the etching rate, direction, and/or duration of RIE are controlled to etch only the part of contact spacer 1003 on the bottom surface, but not on the sidewalls, of opening 1002A or 1002B, i.e., “punching” through contact spacer 1003 in the z-direction to expose only a corresponding second dielectric layer 908 from the bottom, but not other second dielectric layers 908 from the sidewalls.

To form the contact structures, parts of the remainders of the second dielectric layers in the second region of the stack structure can be replaced with interconnect lines, respectively, through the contact structure openings, such that the interconnect lines are in contact with the conductive layers, respectively, in the second region of the stack structure. Referring back to FIG. 11, method 1100 proceeds to operation 1108, as illustrated in FIG. 11, in which at least a part of the exposed second dielectric layer and a part of the high-k dielectric layer surrounding a respective one of the conductive layers are removed through the opening to expose the conductive layer. In some implementations, at least a part of the exposed another second dielectric layer is removed through the another opening. In some implementations, a respective another one of the conductive layers and the another high-k dielectric layer surrounding the another conductive layer are intact when removing the at least part of the exposed another second dielectric layer. In some implementations, the at least part of the exposed another second dielectric layer is removed in the same process as the at least part of the exposed second dielectric layer and the part of the high-k dielectric layer.

As illustrated in FIG. 10B, part of second dielectric layer 908 exposed from the bottom of first opening 1002A, as well as part of first high-k dielectric layer 933A surrounding first conductive layer 923A at the same level, are removed by wet etching to form a first lateral recess 1004A. First lateral recess 1004A can expose first conductive layer 923A and the remainder of first high-k dielectric layer 933A. On the other hand, part of second dielectric layer 908 exposed from the bottom of second opening 1002B is removed by the same wet etching process to form a second lateral recess 1004B, leaving second high-k dielectric layer 933B surrounding second conductive layer 923B at the same level intact. Second lateral recess 1004B does not reach and expose second conductive layer 923B and second high-k dielectric layer 933B, according to some implementations.

In some implementations, the parts of second dielectric layers 908 are wet etched by applying an etchant through first and second openings 1002A and 1002B in the same process, creating first and second lateral recesses 1004A and 1004B each sandwiched between two first dielectric layers 906. The etchant can include phosphoric acid for etching second dielectric layer 908 including silicon nitride. As described above, the etchant (e.g., phosphoric acid) for etching second dielectric layer 908 (e.g., silicon nitride) may attack high-k dielectric layers (e.g., aluminum oxide) to a certain degree (loss of high-k dielectric layers). Thus, the etchant through first opening 1002A, which is closer to conductive portion 929 having conductive layers, can continue to etch first high-k dielectric layer 933A after removing second dielectric layer 908 therebetween. In contrast, in the same process, the etchant through second opening 1002B, which is farther from conductive portion 929 having conductive layers, can be stopped before reaching second high-k dielectric layer 933B.

The etching rate and/or etching time for the first etching process can be controlled to control the amount of the loss of high-k dielectric layers (e.g., first high-k dielectric layer 933A in FIG. 10B), avoiding the bending of corresponding conductive layers (e.g., first conductive layer 923A in FIG. 10B) due to over-etching. In some implementations, the etching rate and/or etching time for second dielectric layers 908 is controlled such that the length (in the y-direction) of first high-k dielectric layer 933A being etched in each wet etching process is between about 20 nm and 200 nm, such as between 20 nm and 200 nm (e.g., 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 180 nm, 190 nm, 200 nm, any range bounded by the lower end by any of these values, or in any range defined by any two of these values). In some implementations, the etching rate and/or etching time for second dielectric layers 908 is controlled such that the length (in the y-direction) of first high-k dielectric layer 933A being etched in each wet etching process is about 100 nm, such as 100 nm.

It is understood that due to the different travel distances of the etchant through different openings (e.g., first and second openings 1002A and 1002B in FIG. 10B), the degree of loss of high-k dielectric layers 933 may vary between high-k dielectric layers 933 in different levels after one wet etching process, and at least one high-k dielectric layers 933 (e.g., second high-k dielectric layer 933B) may be intact after the wet etching process. It is also understood that since the sidewalls of openings (e.g., first and second openings 1002A and 1002B in FIG. 10B) are still covered by contact spacers 1003 (e.g., silicon oxide) that are resistant to the etchant for removing second dielectric layers 908 (e.g., silicon nitride), second dielectric layers 908 at other levels remain intact in dielectric portion 927 after the wet etching process.

Referring back to FIG. 11, method 1100 proceeds to operation 1110, as illustrated in FIG. 11, in which a liner layer is formed through the opening on the exposed conductive layer and a remainder of the high-k dielectric layer. In some implementations, another liner layer is formed through the another opening on a remainder of the another second dielectric layer. The another liner layer can be formed in the same process as the another liner layer. In some implementations, to form the liner layer and the another liner layer, at least one of silicon nitride, silicon oxynitride, or silicon carbon nitride is deposited using ALD.

As illustrated in FIG. 10C, a first liner layer 1006A is formed through first opening 1002A and first lateral recess 1004A on the exposed first conductive layer 923A and first high-k dielectric layer 933A. First liner layer 1006A can be formed on first dielectric layers 906 and contact spacer 1003 forming first opening 1002A and first lateral recess 1004A as well. On the other hand, a second liner layer 1006B is formed through second opening 1002B and second lateral recess 1004B on the remainder of second dielectric layer 908 at the same level as second lateral recess 1004B. Second liner layer 1006B can be formed on first dielectric layers 906 and contact spacer 1003 forming second opening 1002B and second lateral recess 1004B as well. In some implementations, first and second liner layers 1006A and 1006B are formed by depositing a layer of silicon nitride, silicon oxynitride, and/or silicon carbon nitride through first and second openings 1002A and 1002B and first and second lateral recesses 1004A and 1004B in the same one or more thin film deposition processes, such as ALD, CVD, PVD, any other suitable processes, or any combination thereof. The deposition rate and/or duration may be controlled to control the thickness of first and second liner layers 1006A and 1006B, avoiding fully filling first and second lateral recesses 1004A and 1004B, for example, based on the dimensions of first and second lateral recesses 1004A and 1004B and/or the length of first high-k dielectric layer 933A that has been etched when forming first lateral recess 1004A. For example, first and second liner layers 1006A and 1006B may be formed by the same ALD process that can precisely control the thickness of the deposited film. In any event, the thickness of deposited first liner layer 1006A is controlled to at least fully cover the exposed ends of first high-k dielectric layer 933A, according to some implementation.

Referring back to FIG. 11, method 1100 proceeds to operation 1112, as illustrated in FIG. 11, in which a part of the liner layer is removed through the opening to expose the conductive layer again. In some implementations, the remainder of the another second dielectric layer, the another liner layer, and part of the another high-k dielectric layer are removed through the another opening to expose the another conductive layer. The another second dielectric layer, the another liner layer, and the part of the another high-k dielectric layer can be removed in the same process as the part of the liner layer.

As illustrated in FIG. 10D, since second dielectric layer 908 at the same level as second conductive layer 923B has not been fully removed in the first etching process, leaving second conductive layer 923B still being covered by the remainder of second dielectric layer 908, the etching process is repeated for the second time to remove second liner layer 1006B, the remainder of second dielectric layer 908, and part of second high-k dielectric layer 933B (shown in FIG. 10C) through second opening 1002B to expose second conductive layer 923B. As illustrated in FIG. 10D, the same second etching process also removes part of first liner layer 1006A (shown in FIG. 10C) through first opening 1002A to expose first conductive layer 923A again. Similar to the first etching process, the etchant for the second etching process can include phosphoric acid for etching second dielectric layers 908 including silicon nitride, as well as liner layers 1006A and 1006B including silicon nitride, silicon oxynitride, and/or silicon carbon nitride.

The etching rate and/or etching time for the second etching process can be controlled based on the thickness of first and second liner layers 1006A and 1006B, such that second liner layer 1006B can be fully removed while first liner layer 1006A can be partially removed, leaving liner plugs 1008 that can still cover first high-k dielectric layers 933A, as shown in FIG. 10D. That is, first liner layer 1006A can protect first high-k dielectric layers 933A during the second etching process to avoid further loss of first high-k dielectric layers 933A, thereby preventing the bending of first conductive layer 923A.

In some implementations, after removing the part of the liner layer to expose the conductive layer again, an additional liner layer is formed through the opening, on the exposed conductive layer and a remainder of the liner layer, and a part of the additional liner layer is removed from the opening to expose the conductive layer again. It is understood that in case at least one of conductive layers at the same levels as the interconnect lines of contact structures to be formed (e.g., second conductive layer 923B) has not been exposed after the second etching process (e.g., second dielectric layers 908 that cover second conductive layer 923B have not been fully removed), the liner layer deposition and etching processes in operations 1110 and 1112 with respect to FIGS. 10C and 10D may be repeated one or more times until all conductive layers at the same levels as the interconnect lines of contact structures to be formed have been exposed from the corresponding lateral recesses. It is also understood that in case the liner layer deposition and etching processes in operations 1110 and 1112 are repeated, liner plugs 1008 may include multiple portions (corresponding to the number of the repeated processes) with distinguishable interface(s) therebetween, as shown in the example of FIG. 8B. It is further understood that in some examples, at least one liner layer (e.g., second liner layer 1006B) may be fully removed after the liner layer deposition and etching processes without any remainder (liner plugs) covering the corresponding high-k dielectric layers (e.g., second high-k dielectric layers 933B).

Referring back to FIG. 11, method 1100 proceeds to operation 1114, as illustrated in FIG. 11, in which an interconnect line in contact with the exposed conductive layer is formed through the opening. In some implementations, another interconnect line in contact with the exposed another conductive layer is formed through the another opening. The another interconnect line can be formed in the same process as the interconnect line.

As illustrated in FIG. 10E, a first interconnect line 1010A in contact with exposed first conductive layer 923A and liner plugs 1008 is formed by depositing a conductive layer through first opening 1002A to fill first lateral recess 1004A (shown in FIG. 10D). After the same deposition process, a second interconnect line 1010B in contact with exposed second conductive layer 923B and second high-k dielectric layer 933B is formed by depositing the conductive layer through second opening 1002B to fill second lateral recess 1004B (shown in FIG. 10D). The conductive layer, such as a metal layer, can be deposited using one or more thin film deposition processes, such as ALD, CVD, PVD, any other suitable processes, or any combination thereof. The deposition rate and/or duration may be controlled to ensure that interconnect lines 1010A and 1010B can be in contact with the exposed corresponding conductive layers 923A and 923B at the same levels as lateral recesses 1004A and 1004B, respectively. In other words, second dielectric layers 908 exposed from the bottom of the corresponding openings 1002A and 1002B can be partially replaced with corresponding interconnect lines 1010A and 1010B, respectively, in dielectric portion 927 of word line pick-up region 903 without causing bending of first conductive layer 923A, while other second dielectric layers 908 at other levels in dielectric portion 927 remain intact.

In some implementations, vertical interconnects are formed in the openings in contact with the interconnect lines, respectively. As illustrated in FIG. 10E, a first vertical interconnect 1012A and second vertical interconnect 1012B are formed on the sidewalls of first and second openings 1002A and 1002B and are in contact with first and second interconnect lines 1010A and 1010B, respectively. Vertical interconnects 1012A and 1012B can be formed in the same process as forming interconnect lines 1010A and 1010B by depositing the conductive layer not only into lateral recesses 1004A and 1004B, but also on the sidewalls and the bottom surface of openings 1002A and 1002B, using one or more thin film deposition processes, such as ALD, CVD, PVD, any other suitable processes, or any combination thereof.

Although not shown, it is understood that in some examples, a filler may be formed in each of first and second openings 1002A and 1002B after forming vertical interconnects 1012A and 1012B, for example, by depositing a dielectric layer using one or more thin film deposition processes, such as ALD, CVD, PVD, any other suitable processes, or any combination thereof. The excess portions of the conductive layer and dielectric layer for forming vertical interconnects 1012A and 1012B and the fillers may be removed by using chemical mechanical polishing (CMP).

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
channel structures in a first region;
a first contact structure in a dielectric portion of a second region and comprising a vertical interconnect and an interconnect line in contact with the vertical interconnect, the first region and the second region being arranged in a first direction;
a first conductive layer extending in the first region and a conductive portion of the second region, the dielectric portion and the conductive portion of the second region being arranged in a second direction perpendicular to the first direction, wherein the interconnect line of the first contact structure extends in the second direction and is in contact with the first conductive layer;
first high dielectric constant (high-k) dielectric layers, a part of the first conductive layer being sandwiched between the first high-k dielectric layers; and
liner plugs between the interconnect line of the first contact structure and the first high-k dielectric layers in the second direction.

2. The 3D memory device of claim 1, wherein the liner plugs comprise at least one of silicon nitride, silicon oxynitride, or silicon carbon nitride, and the first high-k dielectric layers comprise aluminum oxide.

3. The 3D memory device of claim 1, wherein another part of the first conductive layer is sandwiched between the liner plugs.

4. The 3D memory device of claim 1, wherein each of the liner plugs comprises a plurality of portions.

5. The 3D memory device of claim 1, further comprising:
a second contact structure in the dielectric portion of the second region and comprising a vertical interconnect and an interconnect line in contact with the vertical interconnect;
a second conductive layer extending in the first region and the conductive portion of the second region; and
second high-k dielectric layers, at least a part of the second conductive layer being sandwiched between the second high-k dielectric layers,
wherein the interconnect line of the second contact structure extends in the second direction and is in contact with the second conductive layer and the second high-k dielectric layers.

6. The 3D memory device of claim 5, wherein
the dielectric portion of the second region comprises a stack structure comprising interleaved first dielectric layers and second dielectric layers; and
the first contact structure and the second contact structure extend into the stack structure at different depths.

7. The 3D memory device of claim 6, wherein each of the interconnect lines in the first and second contact structures is sandwiched between two of the first dielectric layers in the stack structure.

8. The 3D memory device of claim 6, further comprising:
additional conductive layers each extending in the first region and the conductive portion of the second region; and
additional high-k dielectric layers, each of the additional conductive layers being sandwiched between a respective one of the additional high-k dielectric layers,
wherein each of the second dielectric layers in the stack structure is in contact with a respective one of the additional high-k dielectric layers.

9. The 3D memory device of claim 6, wherein the first dielectric layers comprise silicon oxide, and the second dielectric layers comprise silicon nitride.

10. A system, comprising:
a three-dimensional (3D) memory device configured to store data, the 3D memory device comprising:
channel structures in a first region;
a contact structure in a dielectric portion of a second region and comprising a vertical interconnect and an interconnect line in contact with the vertical interconnect, the first region and the second region being arranged in a first direction;
a conductive layer extending in the first region and a conductive portion of the second region, the dielectric portion and the conductive portion of the second region being arranged in a second direction perpendicular to the first direction, wherein the interconnect line of the contact structure extends in the second direction and is in contact with the conductive layer;
first high dielectric constant (high-k) dielectric layers, at least part of the first conductive layer being sandwiched between the first high-k dielectric layers; and
liner plugs between the interconnect line of the conductive layer and the high-k dielectric layers in the second direction; and
a memory controller electrically connected to the 3D memory device and configured to operate the channel structures through the conductive layer.

11. A method for forming a three-dimensional (3D) memory device, comprising:
forming a stack structure comprising interleaved first dielectric layers and second dielectric layers;
replacing parts of the second dielectric layers with conductive layers surrounded by high dielectric constant (high-k) dielectric layers;
forming an opening extending into a part of the stack structure comprising the interleaved first dielectric layers and remainders of the second dielectric layers to expose the remainder of a respective one of second dielectric layers;
removing, through the opening, at least a part of the exposed second dielectric layer and a part of the high-k dielectric layer surrounding a respective one of the conductive layers to expose the conductive layer;
forming, through the opening, a liner layer on the exposed conductive layer and a remainder of the high-k dielectric layer;
removing, through the opening, a part of the liner layer to expose the conductive layer again; and
forming, through the opening, an interconnect line in contact with the exposed conductive layer.

12. The method of claim 11, wherein forming the liner layer comprises depositing at least one of silicon nitride, silicon oxynitride, or silicon carbon nitride using atomic layer deposition (ALD).

13. The method of claim 11, wherein the remainder of the high-k dielectric layer is intact when removing the part of the liner layer.

14. The method of claim 11, further comprising:
forming another opening extending into the part of the stack structure to expose the remainder of a respective another one of second dielectric layers; and
removing, through the another opening, at least a part of the exposed another second dielectric layer, wherein a respective another one of the conductive layers and another high-k dielectric layer surrounding the another conductive layer are intact when removing the at least part of the exposed another second dielectric layer.

15. The method of claim 14, wherein the at least part of the exposed another second dielectric layer is removed in a same process as the at least part of the exposed second dielectric layer and the part of the high-k dielectric layer.

16. The method of claim 14, further comprising:
forming, through the another opening, another liner layer on a remainder of the another second dielectric layer;
removing, through the another opening, the remainder of the another second dielectric layer, the another liner layer, and part of the another high-k dielectric layer to expose the another conductive layer; and
forming, through the another opening, another interconnect line in contact with the exposed another conductive layer.

17. The method of claim 16, wherein
the another liner layer is formed in a same process as the another liner layer; and
the another second dielectric layer, the another liner layer, and the part of the another high-k dielectric layer are removed in a same process as the part of the liner layer.

18. The method of claim 11, further comprising:
after removing the part of the liner layer to expose the conductive layer again, forming, through the opening, an additional liner layer on the exposed conductive layer and a remainder of the liner layer; and
removing, through the opening, a part of the additional liner layer to expose the conductive layer again.

19. The method of claim 11, further comprising:
forming channel structures extending through the first dielectric layers and the second dielectric layers in a first region of the stack structure; and
before forming the opening, replacing all the second dielectric layers in the first region and the parts of the second dielectric layers in a second region of the stack structure with the conductive layers surrounded by the high-k dielectric layers.

20. The method of claim 11, wherein the second dielectric layers comprise silicon nitride, and the high-k dielectric layers comprise aluminum oxide.
